(19) United States
(12) Patent Application Publication
(10) Pub. No.: US 2014/0311676 A1
(43) Pub. Date: Oct. 23, 2014

(54) SUBSTRATE MOUNTING TABLE AND PLASMA TREATMENT DEVICE

(71) Applicant: TOKYO ELECTRON LIMITED, Tokyo (JP)

(72) Inventors: Hideyuki Hatoh, Miyagi (JP); Shigeki Doba, Miyagi (JP); Shinya Yamamoto, Miyagi (JP); Satoshi YAMADA, Miyagi (JP); Hiroto Mori, Miyagi (JP); Kenji Ando, Miyagi (JP)

(73) Assignee: TOKYO ELECTRON LIMITED, Tokyo (JP)

(21) Appl. No.: 14/370,279

(22) PCT Filed: Jan. 15, 2013
(86) PCT No.: PCT/JP2013/050570

§ 371 Date: Jul. 2, 2014

(30) Foreign Application Priority Data
Jan. 17, 2012 (JP) 2012-006888

(51) Int. Cl. H01J 37/32

(52) U.S. Cl. CPC H01J 37/32715
USPC 156/345.51

(57) ABSTRACT

A substrate mounting table (94) is equipped with a mounting table (2), an electrostatic chuck (6), and a bevel covering (5). The electrostatic chuck (6) has a supporting surface (6e) which is in contact with the whole of the rear surface of a wafer (W). The annular bevel covering (5) has an outer diameter (DA) which is greater than that of the supporting surface (6e), and an inner diameter (DI) which is smaller than that of the wafer (W). The bevel covering (5) is disposed such that, when viewed from the direction orthogonal to the supporting surface (6e), the bevel covering (5) surrounds the periphery of the wafer (W) supported on the supporting surface (6e).

### TECHNICAL FIELD

The present disclosure relates to a substrate mounting table and a plasma treatment device.

### BACKGROUND ART

In a plasma treatment device, a ring-shaped member called a focus ring may be disposed to surround the periphery of a wafer as a substrate to be processed (see, e.g., Patent Document 1). The focus ring disclosed in Patent Document 1 is disposed around a substrate mounting table provided with a substrate supporting unit which has a supporting surface configured to support the wafer. The supporting surface has a diameter slightly smaller than a diameter of the wafer. Since the focus ring is provided, plasma may be confined, and discontinuity of a bias potential due to an edge surface effect is reduced in a wafer plane so that a uniform and good processing may be performed at the periphery portion of the wafer as well as at the center of the wafer.

However, as disclosed in Patent Document 1, when the top surface of the substrate mounting table is formed to have an area smaller than the wafer, the periphery portion of the wafer protrudes outward from the periphery portion of the top surface of the substrate mounting table. Accordingly, heat of the substrate mounting table may not be sufficiently transferred to the periphery portion of the wafer, and cooling of the periphery portion of the wafer may be insufficient. As a result, an etching property of the periphery portion may be degraded. Accordingly, in a plasma treatment device disclosed in Patent Document 2, a first heat transfer gas diffusion region is formed at the center of the top surface of a substrate mounting table, and a second heat transfer gas diffusion region is formed at the periphery portion of the top surface of the substrate mounting table. By this configuration, the periphery portion of the wafer may be locally cooled or warmed at a high speed.

### PRIOR ART DOCUMENT

### Patent Document

Patent Document 1: Japanese Patent Laid-Open Publication No. 2005-277369
Patent Document 2: Japanese Patent Laid-Open Publication No. 2008-251854

### DISCLOSURE OF THE INVENTION

### Problems to be Solved

In a field of manufacturing semiconductor devices, many attempts have been made to increase the integration degree as miniaturization progresses. Attempts to increase the integration degree per unit area have recently been actively performed through stacking of semiconductor devices, called three-dimensional mounting. In order to form a through electrode in such three-dimensionally mounted semiconductor devices, an attempt to form a through hole in a wafer by using a through-silicon via (TSV) technology has also been performed. Further, an attempt to etch a “bonded wafer” has also been performed, in which the bonded wafer is obtained by bonding a wafer in which the through hole is to be formed to a support wafer through an adhesive.

In a process of forming holes such as a through hole or a via hole, a hole depth is required to be, for example, 100 μm or more. Thus, an etching processing has to be continuously performed until a certain depth is obtained. When the etching processing is continuously performed, a deviation in temperature distribution in a wafer plane may be further significant due to heat input from plasma. In this case, the uniformity in etching rate in the wafer plane or the uniformity in hole depth in the wafer plane may be impaired, and also it may become difficult to realize a vertical hole shape. Thus, in the substrate mounting table disclosed in Patent Document 1 and Patent Document 2, it is required to positively dissipate the heat at the outer periphery portion of the wafer. That is, in the present technology field, it is required to achieve an improvement of uniformity in hole depth in the substrate plane.

### Means to Solve the Problems

The inventors have performed intensive repetitive studies, and as a result, have found that it is important to improve heat transfer efficiency from a substrate to a substrate mounting table in order to solve non-uniformity in heat dissipation, and an employment of a configuration where the entire rear surface of the substrate comes in contact with a supporting surface as the top surface of the mounting table is an excellent solving means. It has been found that in order to employ the solving means, a configuration capable of suitably protecting the periphery of the supporting surface of the mounting table from plasma is required.

That is, a substrate mounting table according to an aspect of the present disclosure includes a substrate supporting unit and a cover member. The substrate supporting unit has a circular supporting surface which comes in contact with an entire rear surface of a substrate to be processed, and supports the substrate by the supporting surface. The cover member is an annular member which has an outer diameter larger than the supporting surface and an inner diameter smaller than the substrate. The cover member is disposed to surround a periphery of the substrate supported by the supporting surface when viewed in a direction perpendicular to the supporting surface.

According to the substrate mounting table, since the entire rear surface of the substrate comes in contact with the supporting surface, a temperature control may be uniformly performed even at the periphery portion of the substrate. Accordingly, a temperature difference in the substrate plane may be reduced, and thus, the uniformity in hole depth may be achieved. The periphery of the supporting surface of the substrate supporting unit and the periphery of the substrate may be covered by using a cover member which has an outer diameter larger than the supporting surface and an inner diameter smaller than the substrate. Thus, the periphery of the supporting surface of the substrate supporting unit and the periphery portion of the substrate are avoided from being directly exposed to plasma, and a temperature control may be uniformly performed even at the periphery portion of the substrate. Accordingly, the uniformity in temperature distribution in the substrate plane is achieved, and thus, an improvement of the in-plane uniformity in hole depth in the substrate plane may be achieved.

In an exemplary embodiment, the supporting surface may be one side surface of the substrate supporting unit formed in a cylindrical shape, and may have a diameter equal to or larger than a diameter of the substrate. Through this configuration, the entire rear surface of the substrate may come in contact with the supporting surface.

In an exemplary embodiment, the cover member may be disposed so that a central axis of the cover member is coaxial with a central axis of the substrate supporting unit. Through this configuration, the periphery of the substrate may be uniformly covered.

In an exemplary embodiment, the cover member may be disposed to cover a portion between a periphery of the substrate and a position spaced 0.3 mm to 1.0 mm apart from the periphery of the substrate. An electric field adjustment may be appropriately performed in the periphery of the substrate by covering the periphery of the substrate in the above-described range.

In an exemplary embodiment, an inner diameter of the cover member may be formed to be smaller than an outer diameter of the substrate by 0.3 mm to 1.0 mm. An electric field adjustment may be appropriately performed in the periphery of the substrate by forming the inner diameter as described above.

In an exemplary embodiment, the cover member may be disposed so that a gap is formed between a front surface of the substrate and a rear surface of the cover member which faces the front surface of the substrate. Through such disposition, even when a bonded substrate which has an increased thickness due to bonding of a plurality of substrates is used besides a conventional substrate, a temperature control may be uniformly performed even at the periphery portion of the substrate while avoiding the periphery of the supporting surface of the substrate supporting unit and the periphery portion of the substrate from being directly exposed to plasma.

In an exemplary embodiment, the cover member may include: a ring-shaped main body having an inner diameter larger than a diameter of the supporting surface, and an eave portion formed at one end side of an inner periphery of the main body and protruding radially inward from the main body to form the inner diameter of the cover member. Through this configuration, the protrusion amount of the eave portion toward a radial inside may be adjusted so as to adjust an electric field in the periphery portion of the substrate.

In an exemplary embodiment, the substrate supporting unit may support a bonded substrate as the substrate, the bonded substrate being formed by bonding a plurality of substrates to each other. Even when the bonded substrate which has an increased thickness due to bonding of the plurality of substrates is used, the above described effect of improving uniformity in substrate temperature may be achieved.

In the exemplary embodiment, the substrate supporting unit may support a bonded substrate as the substrate. The bonded substrate may be formed by bonding a plurality of substrates including substrates made of quartz glass to each other. Even when the bonded substrate including quartz glass that is a heat insulating material is used, the above-described effect of the uniformity in substrate temperature may be exhibited. Thus, the above-described effect of improving the uniformity in substrate temperature may be achieved.

A plasma treatment device according to another aspect of the present disclosure includes: a processing chamber configured to accommodate a circular substrate to be processed and perform a plasma processing; and a substrate mounting table disposed within the processing chamber and configured to support the substrate. The substrate mounting table includes a substrate supporting unit and a cover member. The substrate supporting unit has a circular supporting surface which comes in contact with an entire rear surface of the substrate, and supports the substrate by the supporting surface. The cover member is an annular member having an outer diameter larger than the supporting surface and an inner diameter smaller than the substrate. The cover member is disposed to surround a periphery of the substrate supported by the supporting surface when viewed in a direction perpendicular to the supporting surface.

According to the plasma treatment device, since the entire rear surface of the substrate comes in contact with the supporting surface, a temperature control may be uniformly performed even at the periphery portion of the substrate. Accordingly, a temperature difference in the substrate plane may be reduced, and thus the uniformity in hole depth may be achieved. The periphery of the supporting surface of the substrate supporting unit and the periphery of the substrate may be covered by using a cover member which has an outer diameter larger than the supporting surface and an inner diameter smaller than the substrate. Thus, a temperature control may be uniformly performed even at the periphery portion of the substrate while avoiding the periphery of the supporting surface of the substrate supporting unit and the periphery portion of the substrate from being directly exposed to plasma. Accordingly, the uniformity in temperature distribution in the substrate plane is achieved, and thus, an improvement of the uniformity in hole depth in the substrate plane may be achieved.

### Effect of the Invention

As described above, according to various aspects and exemplary embodiments of the present disclosure, the uniformity in hole depth in the substrate plane may be achieved.

### BRIEF DESCRIPTION OF THE DRAWINGS

FIG. 1 is a schematic cross-sectional view illustrating the configuration of a plasma treatment device according to an exemplary embodiment.

FIG. 2 is a cross-sectional view schematically illustrating surroundings of a bevel covering in an enlarged scale.

FIG. 3 is a first cross-sectional view schematically illustrating the state of a wafer and the bevel covering when the wafer is supported by an electrostatic chuck.

FIG. 4 is a second cross-sectional view schematically illustrating the state of the wafer and the bevel covering when the wafer is supported by the electrostatic chuck.

FIG. 5 is a third cross-sectional view schematically illustrating the state of the wafer and the bevel covering when the wafer is supported by the electrostatic chuck.

FIG. 6 is a fourth cross-sectional view schematically illustrating the state of the wafer and the bevel covering when the wafer is supported by the electrostatic chuck.

FIG. 7 is a cross-sectional view illustrating the state of a wafer supported by the electrostatic chuck and covered by an eave portion of an upper ring member in an enlarged scale.

FIG. 8 is a cross-sectional view for explaining surface roughness generated on the substrate surface of a wafer at the outer periphery portion of the wafer when an upper cover member configured to cover the outer periphery portion of the wafer is not provided.

FIG. 9 is a cross-sectional view for explaining the state where a through hole formed in a wafer is inclined.

FIG. 10 is a graph illustrating measurement results of a vertical inclination angle of a central axis of a through hole formed by etching when the inclination angle was measured at each of points positioned at different distances from the periphery of a wafer.

FIG. 11 is a graph illustrating measurement results of an ashing rate of a resist in an ashing processing using different conditions of Test Examples 1 and 2 when the ashing rate was measured at each of points positioned at different distances from the periphery of a wafer.

FIG. 12 is a graph illustrating measurement results of a thickness of a resist film before and after ashing when the thickness was measured at each of points positioned at different distances from the periphery of a wafer.

FIG. 13 is a cross-sectional view schematically illustrating the configuration of a bonded wafer.

FIG. 14 is a view for explaining a method of manufacturing a bonded wafer, and is a first cross-sectional view schematically illustrating a state of wafers in respective steps.

FIG. 15 is a view for explaining a method of manufacturing a bonded wafer, and is a second cross-sectional view schematically illustrating a state of wafers in respective steps.

FIG. 16 is a schematic view for explaining the difference in behavior between ions and radicals.

FIG. 17 is a graph illustrating the dependence of an etching rate and an ashing rate on a clearance length.

FIG. 18 is a graph illustrating a partial range of FIG. 17.

FIG. 19 is a flow chart of plasma treatment when a height position (a length of a clearance) of a bevel covering is adjusted.

FIG. 20 is a schematic view for explaining a height position (a length of a clearance) of a bevel covering.

FIG. 21 is a graph illustrating the in-plane position dependence of an etching rate and an ashing rate when a height position of a bevel covering is not adjusted.

FIG. 22 is a graph illustrating the in-plane position dependence of an etching rate and an ashing rate when a height position of a bevel covering is adjusted.

FIG. 23 illustrates a simulation result of a temperature in a Si substrate plane. FIG. 23A illustrates a simulation result in a case of mounting on a substrate mounting table of Comparative Example 1, and FIG. 23B illustrates a simulation result in a case of mounting on a substrate mounting table of Example 1.

FIG. 24 illustrates a simulation result of a temperature in a SiO₂ substrate plane. FIG. 24A illustrates a simulation result in a case of mounting on a substrate mounting table of Comparative Example 2, and FIG. 24B illustrates a simulation result in a case of mounting on a substrate mounting table of Example 2.

FIG. 25 illustrates a simulation result of an electric field depending on the central position in a substrate mounting table of Comparative Example 3 and a substrate mounting table of Example 3.

FIG. 26 illustrates conditions for forming holes in substrates mounted on substrate mounting tables of Comparative Example 4, and Examples 4 and 5.

FIG. 27 illustrates a cross-sectional SEM image of holes formed in the substrate mounted on the substrate mounting table of Comparative Example 4.

FIG. 28 illustrates data of the holes illustrated in FIG. 27.

FIG. 29 illustrates a cross-sectional SEM image of holes formed in the substrate mounted on the substrate mounting table of Example 4.

FIG. 30 illustrates data of the holes illustrated in FIG. 29.

FIG. 31 illustrates a cross-sectional SEM image of holes formed in the substrate mounted on the substrate mounting table of Example 5.

FIG. 32 illustrates data of the holes illustrated in FIG. 31.

### DETAILED DESCRIPTION TO EXECUTE THE INVENTION

Hereinafter, various exemplary embodiments will be described in detail with reference to drawings. It is assumed that the same or equivalent parts are given the same numerals in the respective drawings.

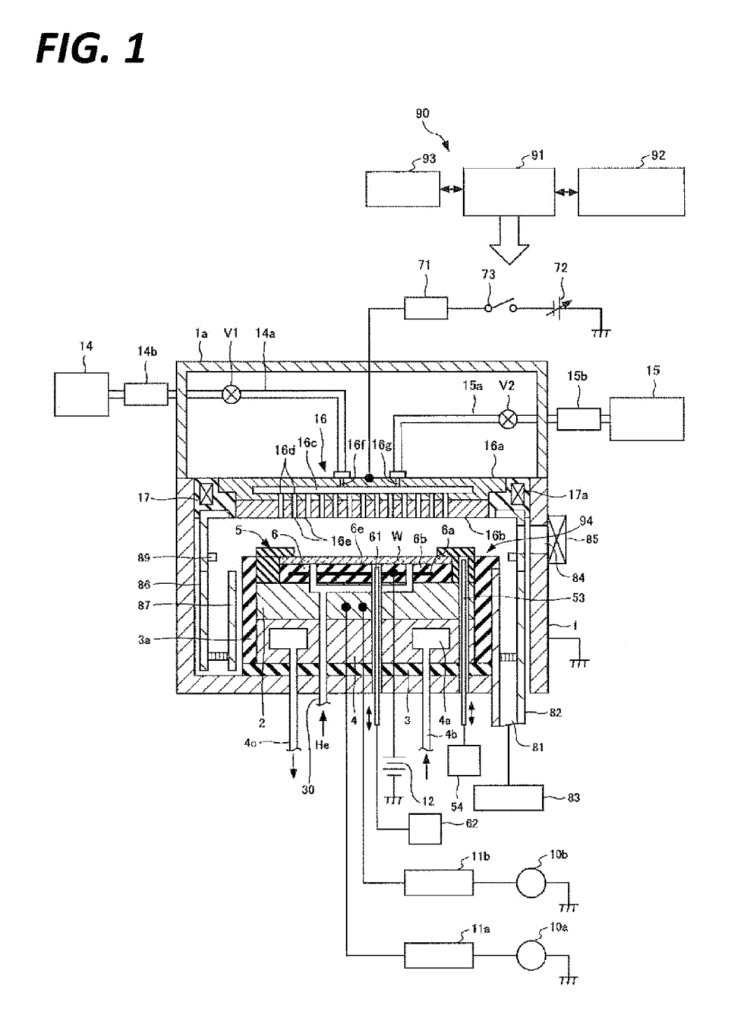

FIG. 1 is a schematic cross-sectional view illustrating the configuration of a plasma treatment device according to the present exemplary embodiment. The plasma treatment device includes a processing chamber 1 which is configured to be airtight and electrically becomes a ground potential. The processing chamber 1 is formed in a cylindrical shape and is made of, for example, aluminum. A substrate mounting table 94 configured to horizontally support a semiconductor wafer (hereinafter, simply referred to as a “wafer”) W as a substrate to be processed is accommodated within the processing chamber 1. The substrate mounting table 94 includes a mounting table 2, an electrostatic chuck 6, and a bevel covering 5. Meanwhile, the mounting table 2 and the electrostatic chuck 6 correspond to a substrate supporting unit in an exemplary embodiment of the present disclosure, and the bevel covering 5 corresponds to a cover member in an exemplary embodiment of the present disclosure. The wafer W is made of, for example, silicon.

The mounting table 2 is formed in a cylindrical shape, and made of, for example, aluminum. The mounting table 2 serves as a lower electrode. The mounting table 2 is supported by a conductive support 4 through an insulating plate 3. A cylindrical inner wall member 3a made of, for example, quartz, is formed to surround the circumference of the mounting table 2 and the support 4. The annular bevel covering 5 is formed on the outer periphery at the top side of the mounting table 2. A detailed configuration of the bevel covering 5 will be described below.

A first RF power source 10a is connected to the mounting table 2 through a first matching unit 11a, and a second RF power source 10b is connected through a second matching unit 11b. The first RF power source 10a is configured to generate plasma, and a high frequency power of a predetermined frequency (27 MHz or more, e.g., 100 MHz) is supplied from the first RF power source 10a to the mounting table 2. The second RF power source 10b is configured to attract ions (bias), and a high frequency power of a predetermined frequency (32 MHz or less, e.g., 13.56 MHz) which is lower than that of the first RF power source 10a is supplied from the second RF power source 10b to the mounting table 2. A shower head 16 serving as an upper electrode is provided above the mounting table 2 to face the mounting table 2 in parallel, and the shower head 16 and the mounting table 2 serve as a pair of electrodes (an upper electrode and a lower electrode). Meanwhile, the shower head 16 as the upper electrode and the mounting table 2 as the lower electrode correspond to an irradiation unit in an exemplary embodiment of the present disclosure.

The electrostatic chuck 6 is provided on the top surface of the mounting table 2. The electrostatic chuck 6 is disk-shaped, and one main surface (one side surface) of the electrostatic chuck 6 serves as a supporting surface 6e configured to support the wafer W. The supporting surface 6e is circular-shaped, and comes in contact with the entire rear surface of the wafer W to support the disk-shaped wafer W. That is, the diameter of the supporting surface 6e is equal to or greater than the diameter of the wafer W, and the supporting surface 6e is configured to come in thermal contact with the entire rear surface of the wafer W. The electrostatic chuck 6 has a structure where an electrode 6a interposed between insulators 6b, and a DC power supply 12 is connected to the electrode 6a. When a DC voltage is applied to the electrode 6a from the DC power supply 12, Coulomb force is generated between the electrode 6a and the wafer W, and the entire rear surface of the wafer W is attracted to the supporting surface 6e by the generated Coulomb force. In this manner, the wafer W is supported by the supporting surface 6e of the electrostatic chuck 6.

A refrigerant path 4a is formed within the support 4, and a refrigerant inlet pipe 4b and a refrigerant outlet pipe 4c are connected to the refrigerant path 4a. An appropriate refrigerant, for example, cooling water, is circulated in the refrigerant path 4a to control the support 4 and the mounting table 2 at a predetermined temperature. A backside gas supply pipe 30 is provided through, for example, the mounting table 2. The backside gas supply pipe 30 is configured to circulate a gas for cold heat transfer (a cooling gas for heat exchange with the wafer W: a backside gas) such as, for example, a helium gas, to the rear surface side of the wafer W. The backside gas supply pipe 30 is connected to a backside gas supply source (not illustrated). Through the above described configuration, the wafer W attracted to and supported by the supporting surface 6e by the electrostatic chuck 6 is controlled at a predetermined temperature. Since the entire rear surface of the wafer W is in contact with the supporting surface 6e, heat transfer between the wafer W and the supporting surface 6e is appropriately performed.

The above described shower head 16 is provided in a top wall portion of the processing chamber 1. The shower head 16 includes a main body 16a and a top ceiling plate 16b which constitutes an electrode plate, and is supported on the top portion of the processing chamber 1 through an insulating member 17. The main body 16a is made of a conductive material such as, for example, aluminum with an anodized surface, and is configured to detachably support the top ceiling plate 16b on the bottom thereof.

A gas diffusion chamber 16c is formed within the main body 16a, and a plurality of gas flowing holes 16d are formed in the bottom portion of the main body 16a to be located at the lower portion of the gas diffusion chamber 16c. Gas introducing holes 16e are formed to extend through the top ceiling plate 16b in the thickness direction and to overlap the gas flowing holes 16d. Through the configuration, a processing gas supplied to the gas diffusion chamber 16c is supplied into the processing chamber 1 through the gas flowing holes 16d and the gas introducing holes 16e to be distributed in a shower form. Meanwhile, a pipe (not illustrated) configured to circulate the refrigerant is provided in, for example, the main body 16a, so as to cool the shower head 16 to a desired temperature during a plasma etching processing.

A gas introducing hole 16f configured to introduce a processing gas for etching into the gas diffusion chamber 16c is formed in the main body 16a. A gas supply pipe 14a is connected to the gas introducing hole 16f, and a processing gas supply source 14 configured to supply the processing gas for etching is connected to the other end of the gas supply pipe 14a. A mass flow controller (MFC) 14b and an opening/closing valve V1 are provided in this order from the upstream side in the gas supply pipe 14a. The processing gas for plasma etching is supplied from the processing gas supply source 14 to the gas diffusion chamber 16c through the gas supply pipe 14a and is supplied into the processing chamber 1 from the gas diffusion chamber 16c through the gas flowing holes 16d and the gas introducing holes 16e to be distributed in a shower form.

A gas introducing hole 16g configured to introduce a processing gas for ashing into the gas diffusion chamber 16c is formed in the main body 16a. A gas supply pipe 15a is connected to the gas introducing hole 16g, and a processing gas supply source 15 configured to supply the processing gas for ashing is connected to the other end of the gas supply pipe 15a. A mass flow controller (MFC) 15b and an opening/closing valve V2 are provided in this order from the upstream side in the gas supply pipe 15a. The processing gas for plasma etching is supplied from the processing gas supply source 15 to the gas diffusion chamber 16c through the gas supply pipe 15a and is supplied into the processing chamber 1 from the gas diffusion chamber 16c through the gas flowing holes 16d and the gas introducing holes 16e to be distributed in a shower form.

A variable DC power supply 72 is electrically connected to the above-described shower head 16 as the upper electrode through a low pass filter (LPF) 71. The variable DC power supply 72 is configured to turn on/off power supply by an on/off switch 73. The current/voltage of the variable DC power supply 72 and the turning on/off of the on/off switch 73 are controlled by a control unit 90 to be described later. Meanwhile, as described below, when a high frequency power is applied to the mounting table 2 from the first RF power source 10a and the second RF power source 10b to generate plasma in the processing space, the on/off switch 73 may be turned on by the control unit 90 as required so that the shower head 16 as the upper electrode is applied with a predetermined DC voltage.

A magnetic field forming mechanism 17a which extends circularly or concentrically is provided in the ceiling portion of the processing chamber 1. The magnetic field forming mechanism 17a serves to facilitate the start (plasma ignition) of a high frequency discharge in the processing space so as to stably maintain the discharge. A cylindrical ground conductor 1a is provided to extend from the side wall of the processing chamber 1 to a position above the height of the shower head 16. The cylindrical ground conductor 1a has a top wall at the top thereof.

An exhaust hole 81 is formed in the bottom portion of the processing chamber 1, and an exhaust device 83 is connected to the exhaust hole 81 through an exhaust tube 82. The exhaust device 83 includes a vacuum pump, and evacuates the inside of the processing chamber 1 to a predetermined vacuum degree by driving the vacuum pump. Meanwhile, a carrying-in/out port 84 for the wafer W is formed in the side wall of the processing chamber 1, and a gate valve 85 configured to open and close the carrying-in/out port 84 is formed in the carrying-in/out port 84.

A deposition shield 86 is formed along the inner wall on the inner lateral side of the processing chamber 1. The deposition shield 86 is configured to suppress etching by-products (deposits) from being attached on the processing chamber 1. A conductive member (GND block) 89 is provided on the deposition shield 86 to be located at substantially the same height as the wafer W, thereby suppressing abnormal discharge. The conductive member 89 is connected so that a potential to ground is controllable. A deposition shield 87 extending along the inner wall member 3a is formed at a lower portion of the deposition shield 86. The deposition shields 86 and 87 are detachable.

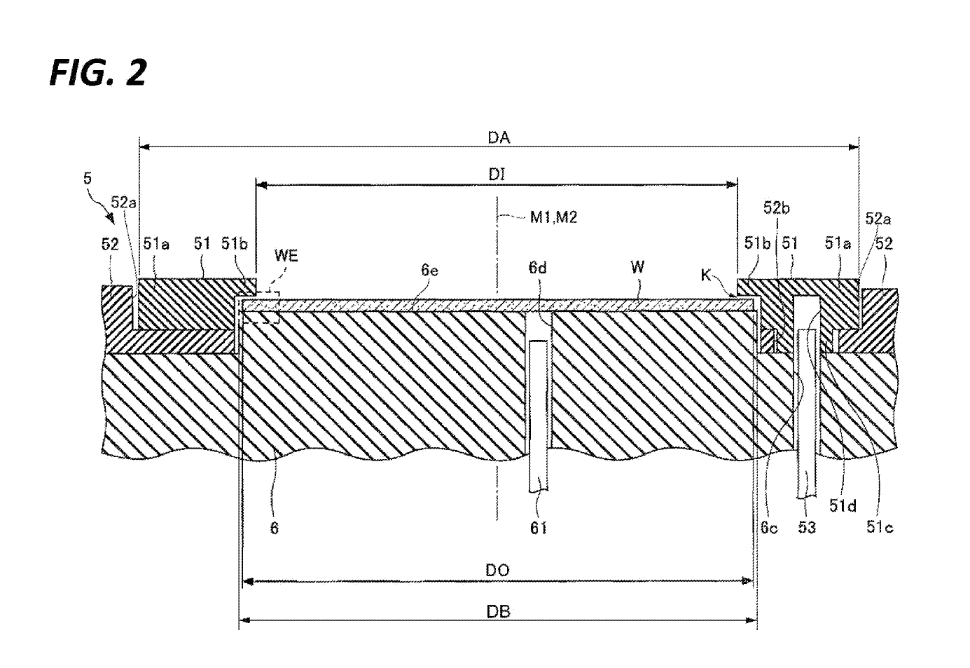

Hereinafter, a detailed configuration of the bevel covering 5 will be described. FIG. 2 is a cross-sectional view schematically illustrating surroundings of the bevel covering 5 in an enlarged scale. As illustrated in FIGS. 1 and 2, the bevel covering 5 includes an upper ring member 51, a lower ring member 52, lift pins 53, and a driving mechanism 54.

The upper ring member 51 is a ring-shaped member and is disposed to surround the periphery of the wafer W supported by the supporting surface 6e when viewed in a direction perpendicular to the supporting surface 6e of the electrostatic chuck 6. The upper ring member 51 includes a main body 51a and an eave portion 51b. The main body 51a is a cylindrical member (a ring-shaped member) having an outer diameter DA and an inner diameter which are larger than a diameter DB of the supporting surface 6e. The eave portion 51b is formed over the entire circumference at one end side of an inner peripheral wall of the main body 51a to protrude radially inward from the inner peripheral wall of the main body 51a. The eave portion 51b is formed to cover the periphery of the supporting surface 6e, and a predetermined region (a periphery portion) in an outer periphery portion WE of the wafer W supported by the electrostatic chuck 6. That is, the eave portion 51b is formed so that a diameter DI of the window formed by the eave portion 51b is smaller than the diameter DB of the supporting surface 6e and a diameter DO of the wafer W. The upper ring member 51 is disposed so that a central axis M1 of the upper ring member 51 is coaxial with a central axis M2 of the mounting table 2 and the electrostatic chuck 6. The upper ring member 51 is disposed so that a gap K is formed between the front surface of the wafer W and the rear surface (that is the rear surface of the eave portion 51b) of the upper ring member 51 which faces the front surface of the wafer W. The upper ring member 51 suppresses plasma from gathering in the predetermined region in the outer periphery portion WE of the wafer W by the eave portion 51b. As for the upper ring member 51, quartz or yttria (Y₂O₃) may be used, and other materials may be used to adjust the electric field in the vicinity of the outer periphery portion WE of the wafer W.

The lower ring member 52 is formed in a ring shape corresponding to the upper ring member 51. A ring-shaped groove 52a is formed on the top surface of the lower ring member 52. The upper ring member 51 is retrained in the horizontal direction by fitting the main body 51a into the ring-shaped groove 52a formed at the top surface of the lower ring member 52.

Through holes 52b vertically penetrating the lower ring member 52 are formed at a plurality of locations (e.g., three locations) along the circumferential direction in the lower ring member 52. A projection portion 51c is formed at a portion of the upper ring member 51 corresponding to each of the through holes 52b. Movement of the upper ring member 51 along the circumferential direction in relation to the lower ring member 52 is restrained by fitting the projection portion 51c into the through hole 52b formed in the lower ring member 52. As for the lower ring member 52, quartz may be used.

A hole portion 51d is formed at the bottom surface of the projection portion 51c of the upper ring member 51. Each of the lift pins 53 is provided vertically movably within a hole portion 6c formed in the electrostatic chuck 6 to correspond to the hole portion 51d formed at the upper ring member 51, and is vertically driven by the driving mechanism 54. When the lift pin 53 is raised, the distal end of the lift pin 53 pushes up the top surface of the hole portion 51d of the upper ring member 51, thereby raising the upper ring member 51.

The electrostatic chuck 6 includes a lift pin 61 and a driving mechanism 62. The lift pin 612 is provided to be vertically movable within a hole portion 6d formed in electrostatic chuck 6, and is vertically driven by the driving mechanism 62. When the lift pin 61 is raised, the distal end of the lift pin 61 pushes up the wafer W, thereby raising the wafer W.

The operation of the plasma treatment device configured as described above is generally controlled by the control unit 90. The control unit 90 includes a process controller 91, a user interface 92, and a storage unit 93. The process controller 91 is provided with a CPU to control respective units of the plasma treatment device.

The user interface 92 includes, for example, a keyboard by which an operation manager performs an input operation of a command to manage the plasma treatment device, or a display which visualizes and displays the operation status of the plasma treatment device.

The storage unit 93 stores recipes in which, for example, control programs (software) configured to implement various processings to be executed in the plasma treatment device under the control of the process controller 91, or processing condition data are recorded. As required, any recipe may be called from the storage unit 93 by, for example, a command from the user interface 92 and the process controller 91 may execute the recipe to perform the desired processing in the plasma treatment device under the control of the process controller 91. As the recipe of control programs or processing condition data, for example, a recipe stored in a computer-readable computer storage medium, such as, for example, a hard disk, a CD, a flexible disk, and a semiconductor memory, may be used. Alternatively, a recipe of control programs or processing condition data may be used by being frequently transmitted from another apparatus through, for example, a dedicated line online.

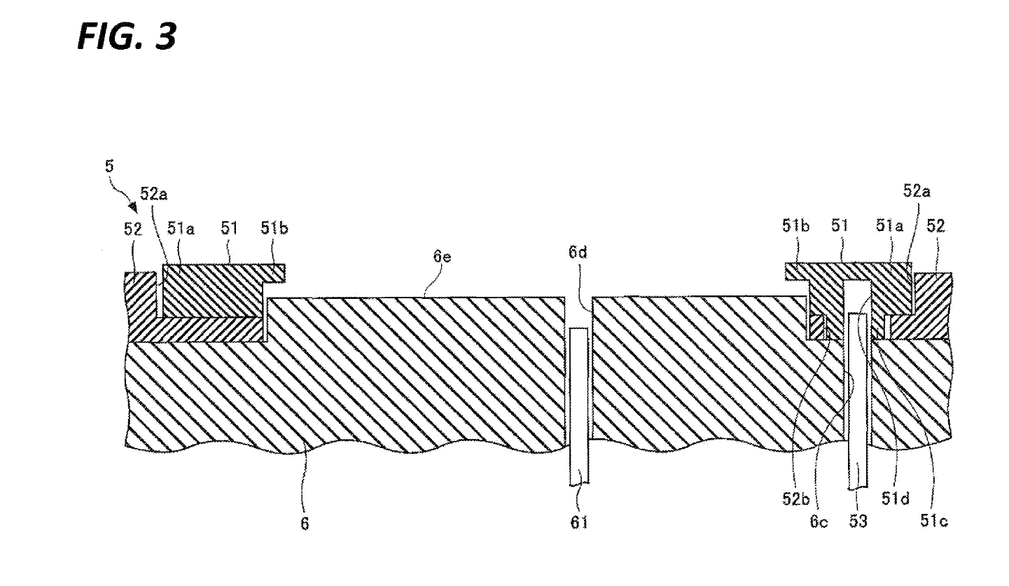

Hereinafter, a plasma etching method will be described. FIGS. 3 to 6 are cross-sectional views schematically illustrating the state of a wafer W and the bevel covering 5 when the wafer W is supported by the electrostatic chuck 6.

First, in a state where a wafer W is not supported by the electrostatic chuck 6 (see FIG. 3), the lift pin 53 is raised by the driving mechanism 54. The upper ring member 51 is pushed up by the raised lift pin 53 to be raised (see FIG. 4).

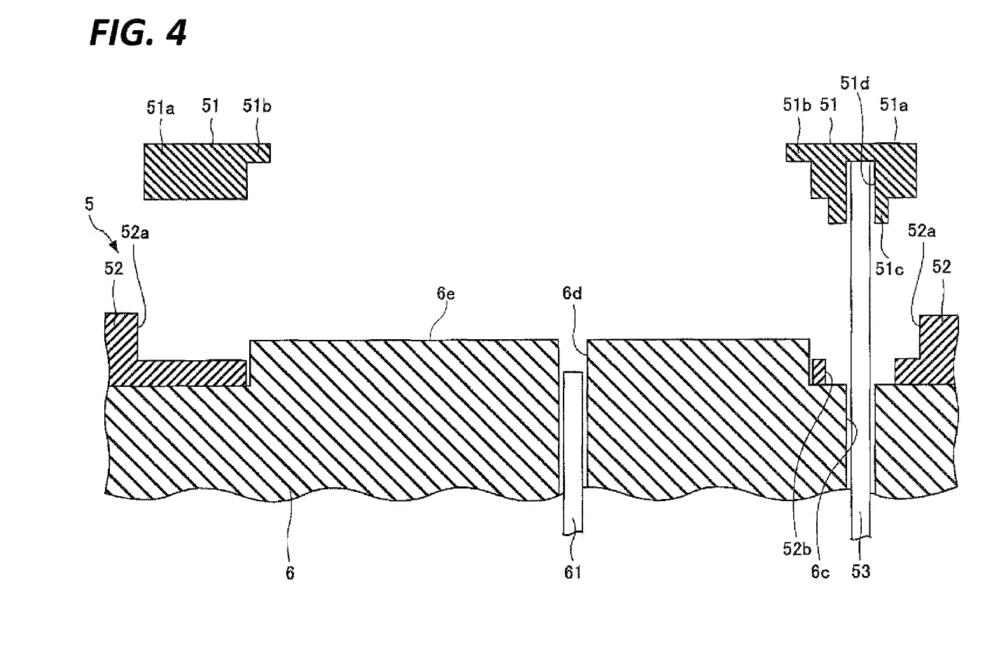

Then, the gate valve 85 is opened, and the wafer W having a front surface formed with a resist pattern is carried onto the electrostatic chuck 6 within the processing chamber 1 by, for example, a conveying robot (not illustrated) through a load-lock chamber (not illustrated) from the carrying-in/out port 84. Then, the lift pin 61 is raised by the driving mechanism 62, and the wafer W is received from the conveying robot by the raised lift pin 61 (see FIG. 5).

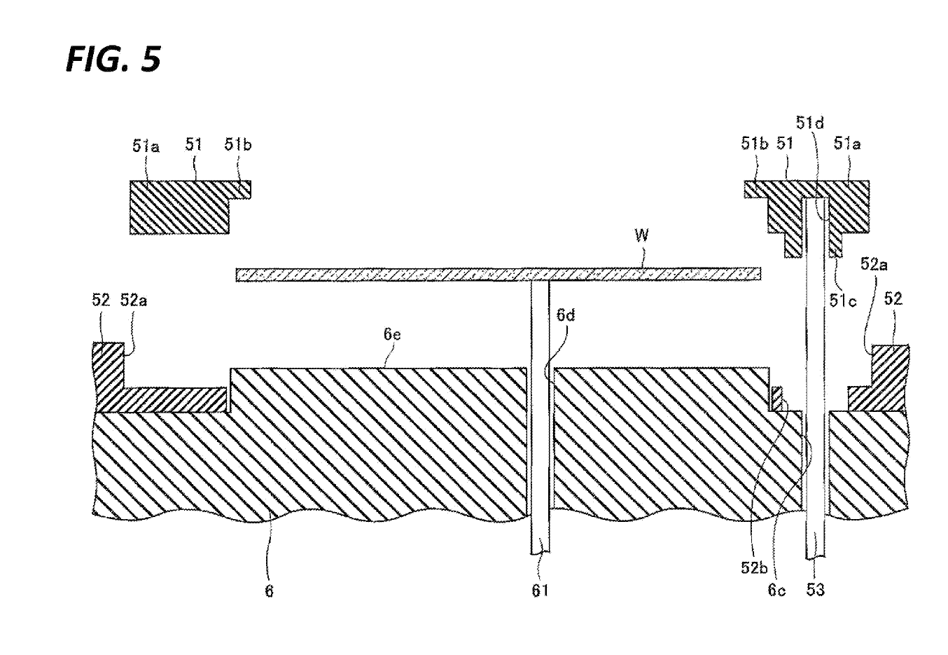

The conveying robot is retreated to the outside of the processing chamber 1, and the gate valve 85 is closed. The lift pin 61 is lowered by the driving mechanism 62 to mount the wafer W on the electrostatic chuck 6 (see FIG. 6). A predetermined DC voltage is applied to the electrode 6a of the electrostatic chuck 6 from the DC power supply 12, and the wafer W is electrostatically attracted by the Coulomb force, and supported. That is, the wafer W is supported while its entire rear surface is in contact with the supporting surface 6e of the electrostatic chuck 6.

The lift pin 53 is lowered by the driving mechanism 54 while the upper ring member 51 is lowered. The state at this time is the same as illustrated in FIG. 2. The periphery of the supporting surface 6e, and the predetermined region in the outer periphery portion WE of the wafer W are covered by the eave portion 51b of the upper ring member 51.

Meanwhile, in the present exemplary embodiment, descriptions have been made on an example where the wafer W is electrostatically attracted by the electrostatic chuck 6 before the upper ring member 51 is lowered. However, the wafer W may be electrostatically attracted by the electrostatic chuck 6 after the upper ring member 51 is lowered.

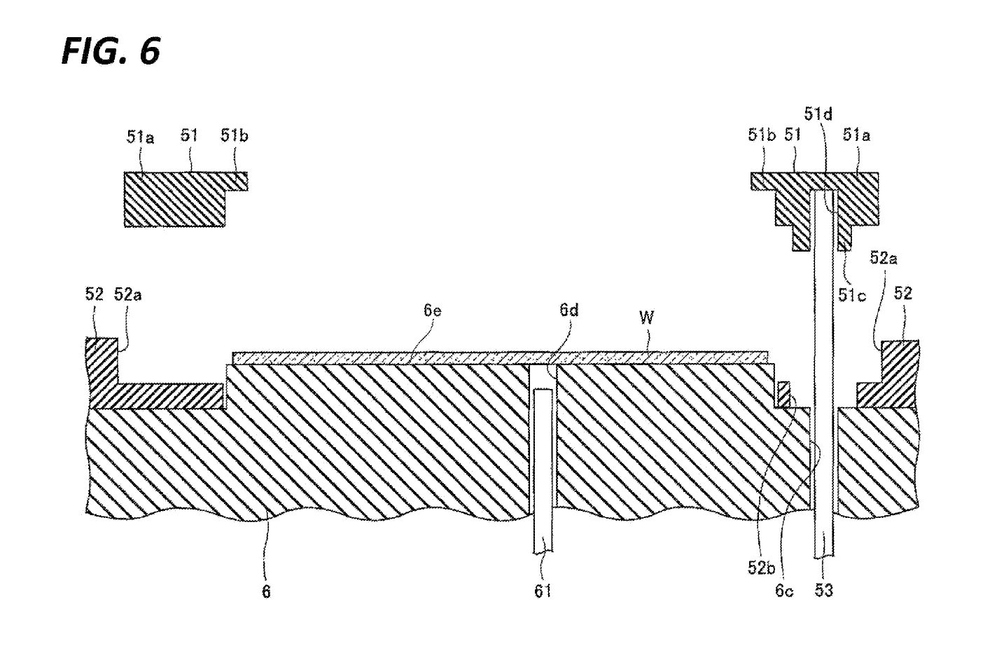

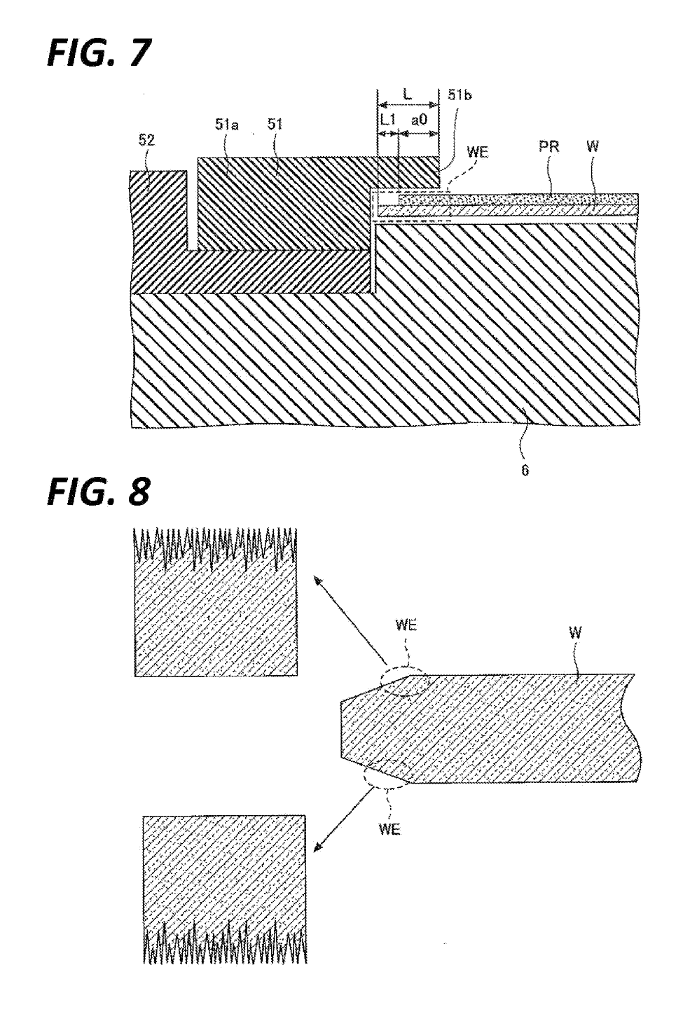

FIG. 7 is a cross-sectional view illustrating the state of the wafer W supported by the electrostatic chuck 6 and covered by the eave portion 51b of the upper ring member 51 in an enlarged scale. As illustrated in FIG. 7, it is assumed that the wafer W is covered by the upper cover member 51 in the region of a predetermined width L from the periphery of the wafer W, in the outer periphery portion WE of the wafer W. It is assumed that the resist pattern is formed on the front surface of the wafer W, but the resist PR is removed and the substrate surface of the wafer W is exposed in the region of a predetermined width L1 from the periphery of the wafer W, in the outer periphery portion WE of the wafer W. Accordingly, as noted in the following Equation (1),

L>L1 (1)
the predetermined width L may be at least greater than the predetermined width L1. Here, when the inner diameter of the upper ring member 51 is DI, and the outer diameter of the wafer W is DO (see FIG. 2), DI, DO, and L satisfy the relationship of the following Equation (2).

L=(DO−DI)/2 (2)

Accordingly, Equations (1) and (2) may satisfy the relationship of the following Equation (3).

DI<DO−2L1 (3)

That is, the inner diameter DI of the eave portion 51b of the upper ring member 51 may be determined based on the outer diameter DO of the wafer W and the predetermined width L1.

Then, the inside of the processing chamber 1 is evacuated through the exhaust hole 81 by the vacuum pump of the exhaust device 83. The plasma of a processing gas for etching is irradiated to the wafer W to perform an etching processing.

In the etching processing, after the inside of the processing chamber 1 is evacuated to a predetermined vacuum degree, a predetermined processing gas (etching gas) is introduced into the processing chamber 1 from the processing gas supply source 14, and the inside of the processing chamber 1 is maintained at a predetermined pressure. When Si used as a substrate of the wafer W is etched by using the resist pattern as a mask, a so-called halogen-based gas such as, for example, Cl₂, Cl₂+HBr, Cl₂+O₂, CF₄+O₂, SF₆, Cl₂+N₂, Cl₂+HCl, or HBr+Cl₂+SF₆ may be used as the processing gas. Alternatively, when a hard mask film made of, for example, SiO₂ or SiN is formed as a single layer or a plurality of layers on the front surface of the wafer W, and is etched by using the resist pattern as a mask, for example, a mixed gas of a CF-based gas such as, for example, CF₄, C₄F₈, CHF₃, CH₃F, or CH₂F₂ with an Ar gas, or the mixed gas added with oxygen as required may be used as the processing gas. In a state where the processing gas is introduced, a high frequency power of a frequency of, for example, 100 MHz is supplied from the first RF power source 10a to the mounting table 2. Also, a high frequency power (for bias) of a frequency of, for example, 13.56 MHz is supplied from the second RF power source 10b to the mounting table 2 in order to attract ions.

When the high frequency power is applied to the mounting table 2 as the lower electrode, an electric field is formed between the shower head 16 as the upper electrode and the mounting table 2 as the lower electrode. Discharge occurs in the processing space where the wafer W is present, and plasma of the processing gas formed by the discharge is irradiated to the wafer W. By the irradiated plasma, the front surface of the wafer W supported by the electrostatic chuck 6 is anisotropically etched using the resist pattern formed on the front surface of the wafer W as a mask in a state where the predetermined region in the outer periphery portion WE is covered by the upper cover member 51.

When the etching processing is finished, subsequently, an ashing processing for removing the remaining resist is performed. That is, plasma of the processing gas for ashing is irradiated to the wafer W to perform an etching processing.

In the ashing processing, in a state where the inside of the processing chamber 1 is placed in a predetermined vacuum degree, a predetermined processing gas (an ashing gas) is introduced into the processing chamber 1 from the processing gas supply source 15, and the inside of the processing chamber 1 is maintained at a predetermined pressure. As the processing gas, a gas such as, for example, O₂ gas, NO gas, N₂O gas, H₂O gas, or O₃ gas may be used. In a state where such a processing gas is introduced, a high frequency power of a frequency of, for example, 100 MHz is supplied from the first RF power source 10a to the mounting table 2. Also, a high frequency power (for bias) of a frequency of, for example, 13.56 MHz is supplied from the second RF power source 10b to the mounting table 2 in order to attract ions.

When the high frequency power is applied to the mounting table 2 as the lower electrode, an electric field is formed between the shower head 16 as the upper electrode and the mounting table 2 as the lower electrode. Discharge occurs in the processing space where the wafer W is present, and plasma of the processing gas formed by the discharge is irradiated to the wafer W. By the irradiated plasma, the resist remaining on the front surface of the wafer W supported by the electrostatic chuck 6 is ashed and removed in a state where the predetermined region in the outer periphery portion WE is covered by the upper cover member 51.

In this manner, after the etching processing and the ashing processing are performed, the supply of the high frequency power, the supply of the DC voltage and the supply of the processing gas are stopped, and then, the wafer W is carried out of the inside of the processing chamber 1 in the reverse sequence to the sequence as described above.

As described above, in the plasma treatment device according to the present exemplary embodiment, when the wafer W is etched, surface roughness may be suppressed from being generated in the predetermined region in the outer periphery portion WE of the wafer W. For example, in a case of a wafer W in which a resist pattern is formed and the resist is removed from the region of a predetermined width from the periphery of the wafer W in the outer periphery portion WE of the wafer W, the substrate surface of the wafer W is exposed and etched in the region. Accordingly, when the exposed substrate surface of the wafer W is exposed to plasma, as illustrated in FIG. 8, surface roughness, so-called black silicon, may be generated on the substrate surface of the wafer W in the predetermined region in the outer periphery portion WE of the wafer W. Meanwhile, in the plasma treatment device according to the present exemplary embodiment, the wafer W is covered by the upper cover member 51 in the region of the predetermined width from the periphery of the wafer W in the outer periphery portion WE of the wafer W. Accordingly, in the etching processing, plasma may be suppressed from gathering in the predetermined region in the outer periphery portion WE of the wafer W. Thus, the exposed substrate surface of the wafer W in the region of the predetermined width from the periphery of the wafer W, in the outer periphery portion WE of the wafer W, is not exposed to plasma so that surface roughness may be suppressed from being generated on the substrate surface of the wafer W in the outer periphery portion WE of the wafer W. That is, the outer periphery portion WE of the wafer W may be protected.

In the plasma treatment device according to the present exemplary embodiment, when the wafer W formed with the resist pattern is etched to form a through hole, a protrusion amount of the eave portion 51b of the upper cover member 51 may be adjusted so that an inclination angle of the through hole in the vertical direction may be suppressed from occurring in the outer periphery portion WE of the wafer W. Hereinafter, this acting effect may be described in detail.

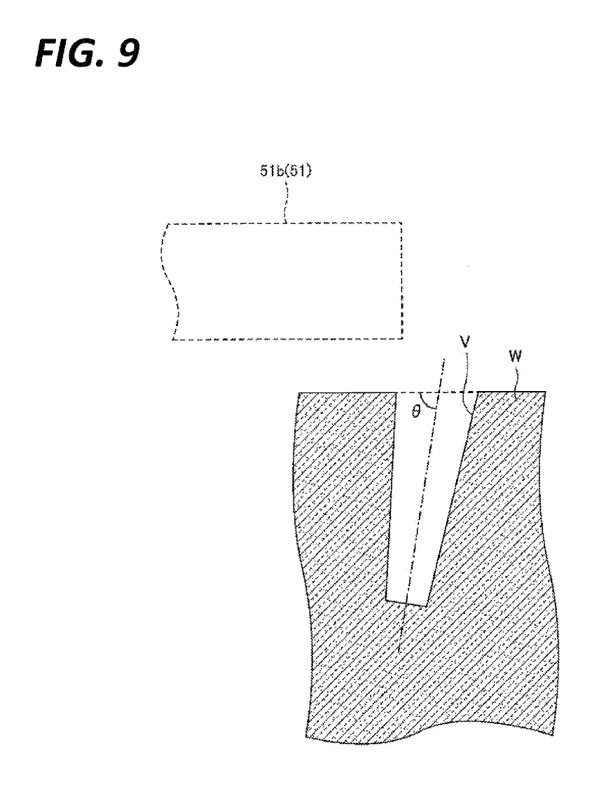

When the upper cover member 51 which covers the outer periphery portion WE of the wafer W is provided, a through hole V formed in the wafer W may be inclined in the vicinity of the distal end of the eave portion 51b of the upper cover member 51. That is, as illustrated in FIG. 9, the central axis of the through hole V is inclined at an inclination angle (90−θ) in relation to the vertical direction when an angle between the central axis and the horizontal direction is assumed to be θ. It is believed that this is because plasma is suppressed from gathering in the outer periphery portion WE of the wafer W due to the eave portion 51b, and the irradiation direction of the plasma is also inclined.

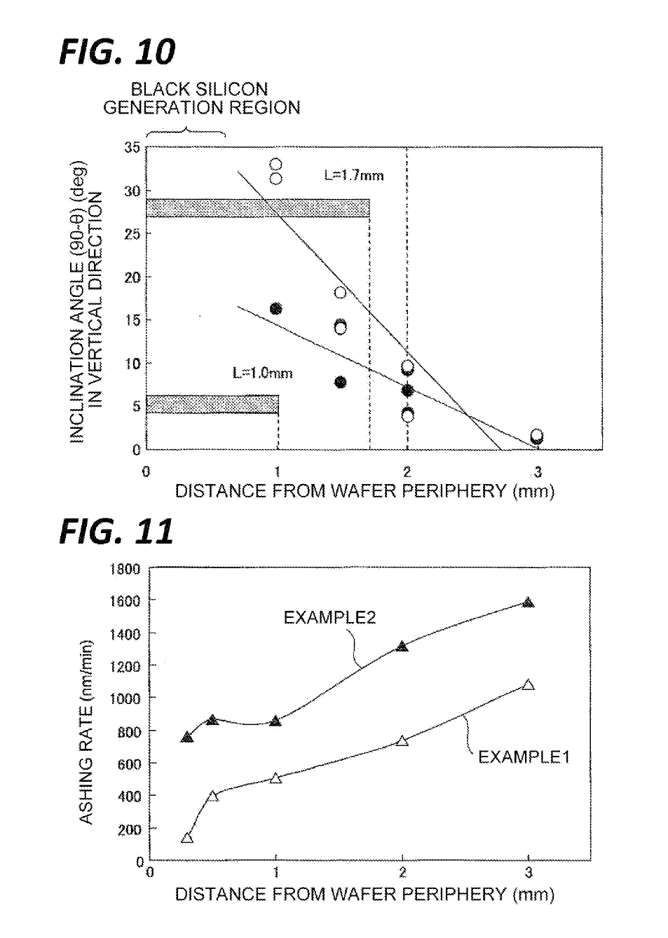

The relationship of the inclination angle (90−θ) and the protrusion amount of the eave portion 51b was measured as described below. Meanwhile, since the measurement as described below was performed to confirm the characteristics caused by the bevel covering 5, the substrate mounting table 94 of which the supporting surface 6e of the electrostatic chuck 6 does not come in contact with the entire rear surface of the wafer W was used to perform the measurement. However, as confirmed in Examples to be described below, the same effect may be exhibited in a case where the measurement is performed using the substrate mounting table 94 of which the electrostatic chuck 6 of the supporting surface 6e comes in contact with the entire rear surface of the wafer W. FIG. 10 is a graph illustrating measurement results of a vertical inclination angle (90−θ) of a central axis of a through hole V formed by etching when the inclination angle was measured at each of points positioned at different distances from the periphery of a wafer W, in examples in which DO=300 mm, and L=1.7 mm (DI=296.6 mm) or L=1.0 mm (DI=298 mm). Black points indicate the case where L=1.0 mm, and white points indicate the case where L=1.7 mm. Meanwhile, in FIG. 10, it is indicated that when inclination angle (90−θ)=0, the central axis is not inclined at all, and as the inclination angle (90−θ) is increased, inclination of the central axis is also increased.

In both cases where L=1.7 mm and L=1.0 mm, in the region farther from the periphery of the wafer W, that is, in the region at the central side of the wafer W, (90−θ) substantially equals to 0, and thus, the through hole V is formed substantially along the vertical direction, and is hardly inclined. In both cases where L=1.7 mm and L=1.0 mm, in the region nearer to the periphery of the wafer W, that is, in the region at the outer periphery portion side of the wafer W, the inclination angle (90−θ) of the through hole V is increased as the through hole V is closer to the distal end of the eave portion 51b of the upper cover member 51.

When L=1.0 mm, as compared to when L=1.7 mm, the inclination angle (90−θ) is decreased at a location at the same distance from the periphery of the wafer W. That is, as the predetermined width L is decreased, the inclination angle (90−θ) of the through hole V in the vertical direction is decreased. This indicates that according to Equation (2), as the inner diameter DI of the eave portion 51b of the upper cover member 51 is increased, the inclination angle (90−θ) of the through hole V in the vertical direction is decreased.

Meanwhile, the protrusion amount may be adjusted in consideration of the positioning accuracy of a relative position of the wafer W in relation to the upper cover member 51. Here, the positioning accuracy of the relative position of the wafer W in relation to the upper cover member 51 is set as ±a0. Further, the positioning accuracy of the wafer W according to the above described conveyance system of the wafer W such as the conveying robot or the lift pin 61 is set as ±a1, and the positioning accuracy of the bevel covering 5 according to a shape accuracy of the lift pin 53 or the bevel covering 5 is set as ±a2. Then, as noted in the following Equation (4),

a0=a1+a2 (4)
an absolute value a0 of the positioning accuracy ±a0 of the relative position of the wafer W in relation to the upper cover member 51 becomes equal to the sum of an absolute value a1 of the positioning accuracy +a1 of the wafer W and an absolute value a2 of the positioning accuracy ±a2 of the bevel covering 5.

Here, it is desirable that the predetermined width L is set as a value which does not become less than the predetermined width L1 even if a variation according to the positioning accuracy is taken into account. This is because if the predetermined width L is less than the predetermined width L1, a region of the outer periphery portion WE of the wafer W, on which the resist is removed and the substrate surface of the wafer W is exposed, is exposed to plasma. Accordingly, in the range (L±a0) of the predetermined width L obtained by taking a variation according to the positioning accuracy into consideration, when a minimum value (L−a0) becomes equal to the predetermined width L1, the outer periphery portion WE of the wafer W may be protected to suppress the generation of the surface roughness, and also the inclination angle (90−θ) of the through hole V in the vertical direction may be minimized. FIG. 7 illustrates a case where a minimum value (L−a0) of the predetermined width L equals to the width L1 when the variation according to the positioning accuracy is taken into consideration.

Otherwise, when the variation according to the positioning accuracy is taken into consideration, the minimum value (L−a0) of the predetermined width L may become equal to a value (L1+a) obtained by adding the predetermined width L1 with a predetermined margin α. That is, as noted in the following Equation (5),

L=L1+(a0+α) (5)
the predetermined width L may be determined to be equal to the sum of the predetermined width L1, and a predetermined width (a0+α) based on the positioning accuracy a0 of the relative position of the wafer W in relation to the upper cover member 51 and the margin α. Accordingly, Equations (5) and (2) may satisfy the relationship of the following Equation (6).

DI=DO−2(L1+a0+α) (6)

That is, the inner diameter DI of the eave portion 51b of the upper ring member 51 may be determined based on the outer diameter DO of the wafer W, the predetermined width L1, and the predetermined width (a0+α) according to the positioning accuracy a0. Accordingly, the outer periphery portion WE of the wafer W may be protected to suppress the generation of the surface roughness, and also the inclination angle (90−θ) of the through hole V in the vertical direction may be minimized.

In the plasma treatment device according to the present exemplary embodiment, the material for the bevel covering 5 is not particularly limited. Hereinafter, measurement results of an angle (θ) of a through hole V with respect to the horizontal direction according to a material of the bevel covering 5 will be described. Here, the measurement was performed on three examples, in which L=1.7 mm and quartz was used for the upper ring member 51, L=1.7 mm and yttria (Y₂O₃) was used for the upper ring member 51, and L=1.0 mm and yttria (Y₂O₃) was used for the upper ring member 51. Table 1 illustrates the measurement results of an angle (θ°) of each formed through hole V with respect to the horizontal direction, when the angle (θ°) was measured at each of points positioned at different distances from the center of the wafer.

TABLE 1

| | | Distance from | | |
|---|---|---|---|---|
| | DI | Wafer Center (mm) | | |
| Material | (mm) | 145 | 147 | 148 |
| Quartz | 296.6 | 90 | 88.6 | 83.3 |
| Yttria (Y₂O₃) | 296.6 | 90 | 89.5 | 83.8 |
| Yttria (Y₂O₃) | 298 | 90 | 90 | 86.5 |

In comparison of the results as noted in the upper and middle parts of Table 1, when the same inner diameter (DI=296.6 mm) is employed, substantially the same angle (θ) substantially close to 90° may be obtained in an upper ring member 51 made of yttria (Y₂O₃) and an upper ring member 51 made of quartz. Since yttria is more excellent in plasma resistance than quartz, the outer periphery portion WE of the wafer W may be protected by using yttria as the upper ring member 51, and thus the lifetime of the upper ring member 51 may be prolonged.

Meanwhile, in comparison of the results as noted in the middle and lower parts in Table 1, when the upper ring members 51 made of yttria (Y₂O₃) with different inner diameters (DI=296.6 mm) are used, an angle (θ) closer to 90° may be obtained, as the inner diameter DI of the upper ring member 51 is increased. Accordingly, as the inner diameter DI of the upper ring member 51 is increased, an inclination angle of the through hole V in the vertical direction may be more suppressed from occurring.

As described above, the inclination angle (90−θ) of the through hole V in the vertical direction is decreased as the inner diameter DI of the eave portion 51b of the upper cover member 51 is increased, and a larger film formation area may be secured as the inner diameter DI is as large as possible. By taking these facts into consideration, for example, it is desirable that the distance from the periphery of the wafer W (that is, L illustrated in FIG. 7) is set to be smaller than 1.0 mm. Meanwhile, in a range not causing black silicon, the inner diameter DI is required to be increased. Accordingly, the eave portion 51b may protrude as long as the distance from the periphery of the wafer W (that is, L illustrated in FIG. 7) does not become smaller than, for example, 0.3 mm. In this manner, L may be set in a range from 0.3 mm to 1.0 mm. That is, the inner diameter DI may be formed to be smaller than the outer diameter DO of the wafer W by 0.3 mm to 1.0 mm.

In the plasma treatment device according to the present exemplary embodiment, when a resist remaining on the wafer W is ashed, an ashing rate may be suppressed from being lowered in the outer periphery portion WE of the wafer W by adjusting the protrusion amount of the eave portion 51b of the upper cover member 51. Hereinafter, descriptions will be made on suppression of lowering of the ashing rate.

FIG. 11 is a graph illustrating measurement results of an ashing rate of a resist in an ashing processing using different conditions (Test Examples 1 and 2) when the ashing rate was measured at each of points positioned at different distances from the periphery of a wafer W. Conditions for Test Examples 1 and 2 are as follows.

### Test Example 1

Pressure within treatment device: 300 mTorr
Power of high-frequency power source (upper electrode/lower electrode): 0/1500 W
Flow rate of processing gas: O₂=300 sccm
Processing time: 30 sec

### Test Example 2

Pressure within treatment device: 100 mTorr
Power of high-frequency power source (upper electrode/lower electrode): 0/2000 W
Flow rate of processing gas: O₂=1300 sccm
Processing time: 30 sec

As illustrated in FIG. 11, as a distance from the periphery of a wafer W is reduced, that is, at a location nearer to the wafer outer periphery side, the ashing rate is reduced. This indicates that plasma is suppressed from gathering in an outer periphery portion WE of the wafer W by the upper cover member 51 and an ashing rate is reduced in the vicinity of the upper cover member 51. In Test Example 1, the ratio of the ashing rate at a location 0.3 mm from the periphery with respect to the ashing rate at a location 3 mm from the periphery is about 10%.

However, in Test Example 2, the ashing rate is higher in the entire region than in Test Example 1. Also, the ratio of the ashing rate at a location 0.3 mm from the periphery with respect to the ashing rate at a location 3 mm from the periphery is increased up to about 50%. Accordingly, a reduction of the ashing rate may be suppressed even in the outer periphery portion WE of the wafer W covered by the upper cover member 51 by optimizing process conditions.

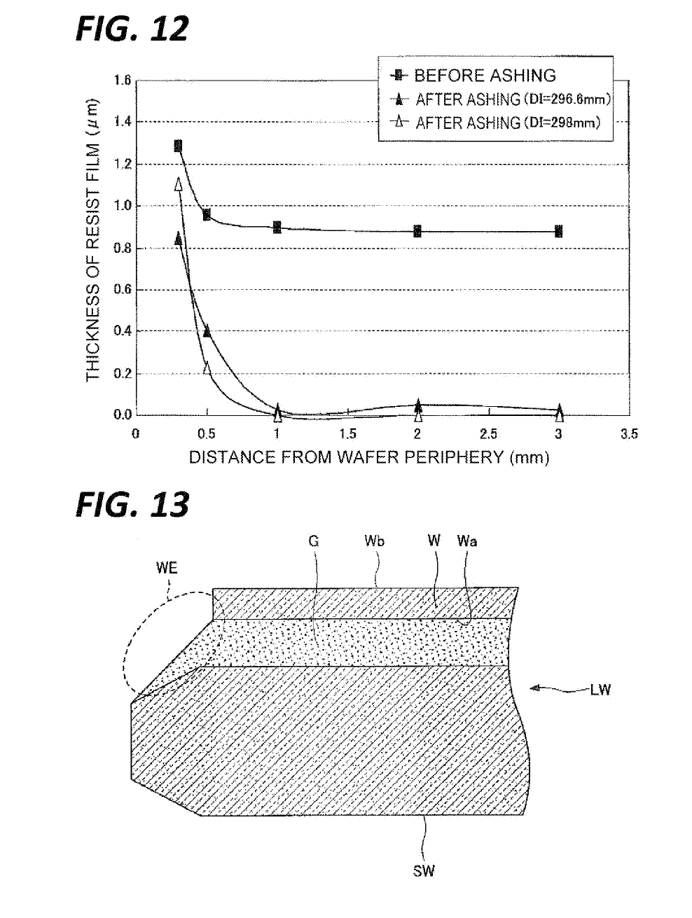

FIG. 12 is a graph illustrating measurement results of a thickness of a resist film before and after ashing when the thickness was measured at each of points positioned at different distances from the periphery of a wafer W in a case where an inner diameter DI of the upper cover member 51 is 296.6 mm and 298 mm. Meanwhile, it is assumed that regardless of the inner diameter of the upper cover member 51, the thickness of the resist film before ashing is unchanged.

At a location 0.5 mm from the periphery of the wafer W, the thickness of the resist film after ashing when DI=298 mm is smaller than the thickness of the resist film after ashing when DI=296.6 mm. That is, when the inner diameter of the upper cover member 51 is increased, the reduction of the ashing rate may be suppressed even in the outer periphery portion WE of the wafer W covered by the upper cover member 51.

In the plasma treatment device according to the present exemplary embodiment, since the entire rear surface of the wafer W comes in contact with the supporting surface 6e, a temperature control may be uniformly performed even in the outer periphery portion WE of the wafer W. Since a radical reaction dominantly contributes to etching, a temperature increase of the wafer W due to plasma irradiation is required to be controlled. In particular, in a process of forming a through hole or a via hole, the wafer W needs to be exposed to plasma for a long time, and thus it is necessary to actively control a temperature increase of the wafer W due to plasma irradiation. When a temperature control for suppressing a temperature difference in the wafer W plane is not performed, an etching rate in the wafer W plane becomes non-uniform, thereby affecting non-uniformity in hole depth. In the plasma treatment device according to the present exemplary embodiment, since a configuration where the entire rear surface of the wafer W comes in contact with the supporting surface 6e is employed, a temperature control may be uniformly performed even in the outer periphery portion WE of the wafer W, and the etching rate in the wafer W plane may become uniform. Accordingly, the uniformity in hole depth in the wafer W plane may be improved. When a diameter DS of the supporting surface 6e is simply set to be larger than a diameter DO of the wafer W, the supporting surface 6e may be directly exposed to plasma. In the plasma treatment device according to the present exemplary embodiment, since the bevel covering 5 which covers the periphery of the supporting surface 6e, and the region of a predetermined width from the periphery of the wafer W at the outer periphery portion WE of the wafer W is used, the periphery of the supporting surface 6e, and the region of the predetermined width from the periphery of the wafer W at the outer periphery portion WE of the wafer W may be suppressed from being directly exposed to plasma. Also, an electric field may be adjusted by adjusting the protrusion amount of the eave portion 5b of the bevel covering 5 toward a radial inside, so that a hole shape may be optimized. That is, it is possible to achieve both the optimization of the hole shape, and the improvement of uniformity in hole depth in the wafer W plane.

Meanwhile, a wafer used in the exemplary embodiment as described above may be a bonded substrate (a bonded wafer) formed by bonding a plurality of wafers to each other. FIG. 13 is a cross-sectional view schematically illustrating the configuration of a bonded wafer LW. The bonded wafer LW includes a device wafer W and a support wafer SW. The device wafer W is a substrate having a front surface Wa formed with a semiconductor device such as, for example, a transistor. The support wafer SW is a substrate configured to reinforce the device wafer W when the device wafer W is thinned by grinding a rear surface Wb. The support wafer SW is made of, for example, quartz glass. The device wafer W is bonded to the support wafer SW through an adhesive G. The bonded substrate is employed in, for example, semiconductor devices to be three-dimensionally mounted. In the bonded substrate, a through hole is formed using a TSV (Through-Silicon Via) technology so that a through electrode is formed.

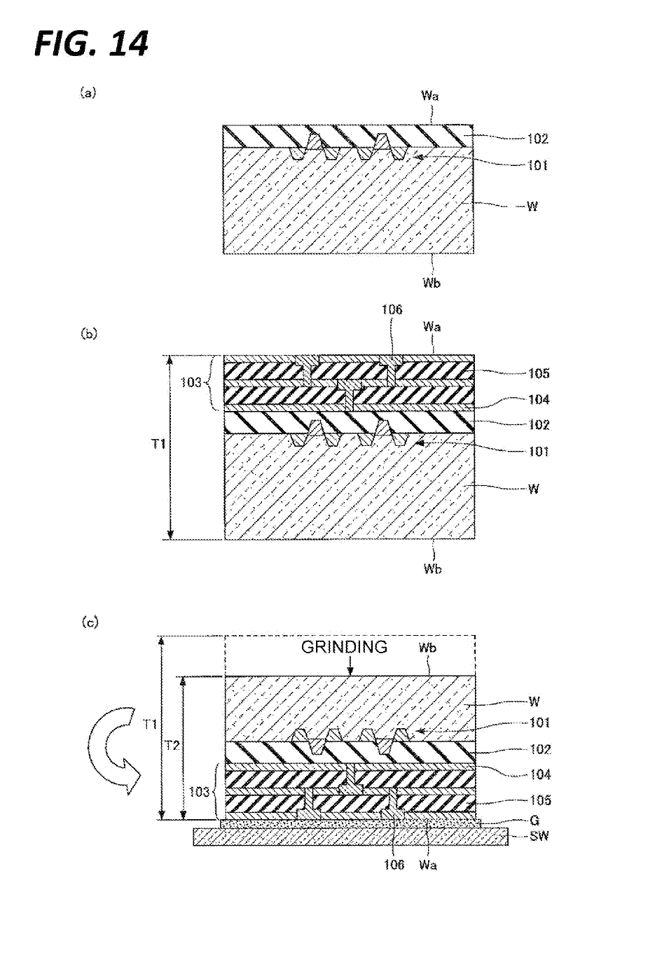

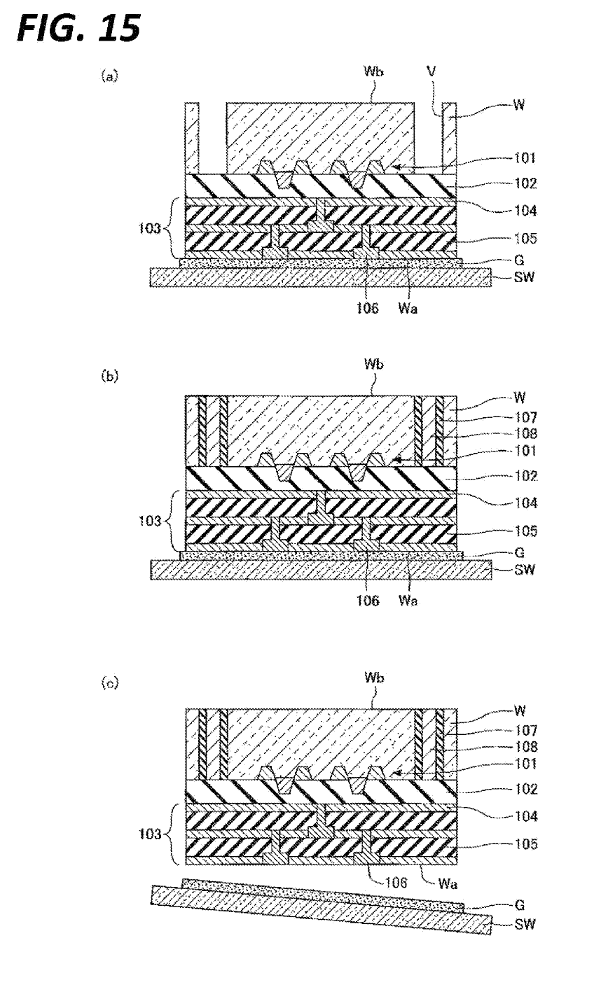

FIGS. 14 and 15 are views for explaining a method of manufacturing a semiconductor device which employs a bonded wafer, and are cross-sectional views schematically illustrating a state of wafers in respective steps.

First, a transistor 101 is formed on a front surface of a device wafer W formed of, for example, a silicon wafer, and an interlayer insulating film 102 is formed on the device wafer W formed with the transistor 101 (FIG. 14A).

Then, a wiring structure 103 is formed on the interlayer insulating film 102. A wiring layer 104 and an insulating film 105 are alternately laminated on the interlayer insulating film 102 to form via holes 106 for electrically connecting the upper and lower wiring layers 104 through the insulating films 105 (FIG. 14B).

Then, the device wafer W is inverted upside down, and is bonded to a support wafer SW through an adhesive G to prepare a bonded wafer LW. The support wafer SW serves as a support configured to reinforce the device wafer W when the device wafer W is thinned by grinding a rear surface Wb, and to suppress warping of the device wafer W. The support wafer SW is formed of, for example, a silicon wafer. The bonded wafer LW is supported by a supporting unit provided in, for example, a grinding device, and the rear surface Wb side of the wafer W is ground, and thinned so that a thickness T1 is changed to a predetermined thickness T2 through grinding (FIG. 14C). The predetermined thickness T2 may be set, for example, in a range from 50 μm to 200 μm.

In FIG. 14, for the convenience of illustration, the interlayer insulating film 102 and the wiring structure 103 are illustrated with exaggerated thicknesses, but in actuality, the interlayer insulating film 102 and the wiring structure 103 have thicknesses much smaller than the thickness of the substrate itself of the wafer W (the same applies to FIG. 15).

The adhesive G is exposed in an outer periphery portion WE of the bonded wafer LW. Then, a resist is applied to the rear surface Wb of the wafer W, exposed and developed to form a resist pattern (not illustrated). The bonded wafer LW having the resist pattern formed on the rear surface Wb of the wafer W is etched in the same manner as in the plasma etching method as described above to form through holes V. The resist remaining on the rear surface Wb of the wafer W of the bonded wafer LW in which the through holes V are formed is removed through ashing in the same manner as in the plasma etching method as described above (FIG. 15A). The diameter of the through hole V may be set in a range from, for example, 1 μm to 10 μm. The depth of the through hole V corresponds to the thickness of the substrate itself of the wafer W which is thinned by grinding the rear surface Wb of the wafer W, and as described above, may be set in a range from, for example, 50 μm to 200 μm.

Then, an insulating film 107 made of, for example, polyimide, is formed to cover the inner circumferential surfaces of the through holes V, and through electrodes 108 are formed within the through holes V having inner circumferential surfaces covered with the insulating film 107 through, for example, an electrolytic plating method (FIG. 15B).

Then, the support wafer SW is peeled from the wafer W to obtain the wafer W which is thinned and formed with the through electrodes 108. The support wafer SW may be peeled by reducing an adhesive strength of a photoreactive adhesive G through irradiation of, for example, ultraviolet light (UV light) (FIG. 15C).

The outer periphery region (periphery portion) of a predetermined width from the periphery of the bonded wafer LW, in an outer periphery portion WE of the bonded wafer LW, is covered by an upper cover member. Accordingly, plasma may be suppressed from gathering in the outer periphery portion WE of the bonded wafer LW in the etching processing. Accordingly, in the outer periphery portion WE of the wafer W of the bonded wafer LW, specifically in the region of a predetermined width from the periphery of the wafer W, an exposed substrate surface of the wafer W is not exposed to plasma. Thus, surface roughness may be suppressed from being generated on the substrate surface of the wafer W in the outer periphery portion WE of the wafer W.

In the outer periphery portion WE of the bonded wafer LW, the adhesive G is exposed between the wafer W and the support wafer SW. Accordingly, the adhesive G exposed in the outer periphery portion WE of the bonded wafer LW is not exposed to the plasma and thus, the adhesive G is suppressed from being peeled off Consequently, occurrence of dusts and separation of the wafers may be prevented. Further, it is possible to prevent the outer periphery portion WE of the bonded wafer LW from becoming brittle and cracking. That is, the outer periphery portion WE of the bonded wafer LW may be protected.

Since the entire rear surface of the bonded wafer LW comes in contact with the supporting surface 6e, a temperature control may be uniformly performed even in the outer periphery portion WE of the bonded wafer LW. Since a radical reaction dominantly contributes to silicon etching, a uniformity in hole depth or a vertical hole shape may be achieved by uniformly performing a temperature control even in the outer periphery portion WE of the bonded wafer LW. When the bonded wafer LW is used, the thickness is increased as compared to a case where a single wafer W is used, and thus, a temperature variation is likely to occur in the wafer plane. In particular, when quartz glass is employed as the support wafer SW, the support wafer SW serves as an insulating material. Thus, a temperature difference tends to be further significant in the wafer plane. Accordingly, when a configuration where the entire rear surface of the wafer LW comes in contact with the supporting surface 6e is employed, a temperature control may be uniformly performed even in the outer periphery portion WE of the wafer LW, and the etching rate in the wafer LW plane may become uniform. Accordingly, the uniformity in hole depth in the wafer LW plane may be improved. When a diameter DS of the supporting surface 6e is simply set to be larger than a diameter of the wafer LW, the supporting surface 6e may be directly exposed to plasma. In the plasma treatment device according to the present exemplary embodiment, since the bevel covering 5 which covers the periphery of the supporting surface 6e, and the region of a predetermined width from the periphery of the wafer LW at the outer periphery portion WE of the wafer LW is used, the periphery of the supporting surface 6e, and the region of the predetermined width from the periphery of the wafer LW at the outer periphery portion WE of the wafer LW may be suppressed from being directly exposed to plasma. Also, an electric field may be adjusted by adjusting the protrusion amount of the eave portion 5b of the bevel covering 5 toward a radial inside, so that a hole shape may be optimized. That is, it is possible to achieve both the optimization of the hole shape, and the improvement of uniformity in hole depth in the wafer W plane.

In the exemplary embodiment as described above, as illustrated in FIG. 2, the etching processing and the ashing processing are performed in a state where the bevel covering 5 is disposed on the electrostatic chuck 6, but the height position of the bevel covering 5 may be changed according to the purpose of the plasma treatment. That is, the plasma treatment may be performed while the upper ring member 51 is maintained to be spaced apart from the lower ring member 52. For example, when a through hole is formed in the wafer W by using a TSV technology, deposits may be adhered on the wafer W. The deposits are made of an inorganic material, and thus may be removed through an ion etching processing. However, it is difficult to remove deposits adhered on an end portion of the wafer W covered by the bevel covering 5. Also, when a resist made of an organic material is ashed, the resist on the end portion of the wafer W may not be uniformly removed due to an influence of the eave portion 51b of the bevel covering 5. This will be described in detail.

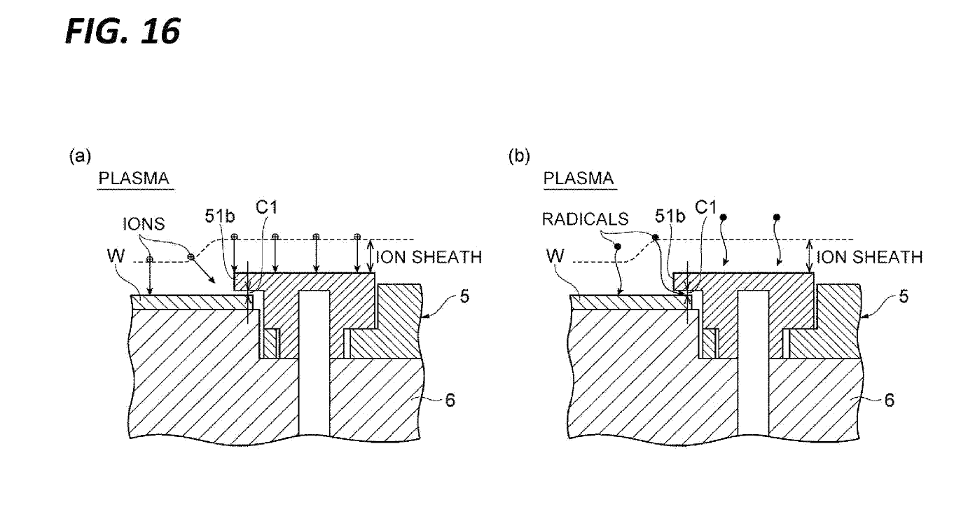

FIG. 16 is a schematic view for explaining the difference in behavior between ions and radicals in the plasma treatment. FIG. 16A is a view for explaining the behavior of ions in the plasma treatment, and FIG. 16B is a view for explaining the behavior of radicals in the plasma treatment. As illustrated in FIGS. 16A and 16B, when plasma is generated, an ion sheath is formed between the plasma and a boundary (e.g., the inner wall of the processing chamber 1, the top surface of the wafer W, and the top surface of the bevel covering 5).

As illustrated in FIG. 16A, ions are accelerated in a direction perpendicular to an equipotential electric field surface. Ions move linearly, and thus collide with the wafer W or the eave portion 51b before entering into a clearance C1 between the bottom surface of the eave portion 51b of the bevel covering 5 and the top surface of the wafer W. Accordingly, there is a tendency that it is difficult for ions to enter into the clearance C1. For example, when the length of the clearance C1 is shorter than the length of the ion sheath, ions hardly enter into the clearance C1. Thus, in a state where the bevel covering 5 is disposed on the electrostatic chuck 6, it is difficult to remove the deposits made of an inorganic material adhered on the end portion of the wafer W.

As illustrated in FIG. 16B, in an isotropic ashing processing performed using a reaction by radicals, radicals are freely diffused regardless of electric charges or an ion sheath. Accordingly, it can be said that radicals may easily enter into the clearance C1 as compared to ions. However, even in a case of the ashing processing using radicals, there is a tendency that the ashing rate at the end portion of the wafer W located within the clearance C1 is smaller than the ashing rate at the central portion of the wafer W. Hereinafter, measurement data will be described.

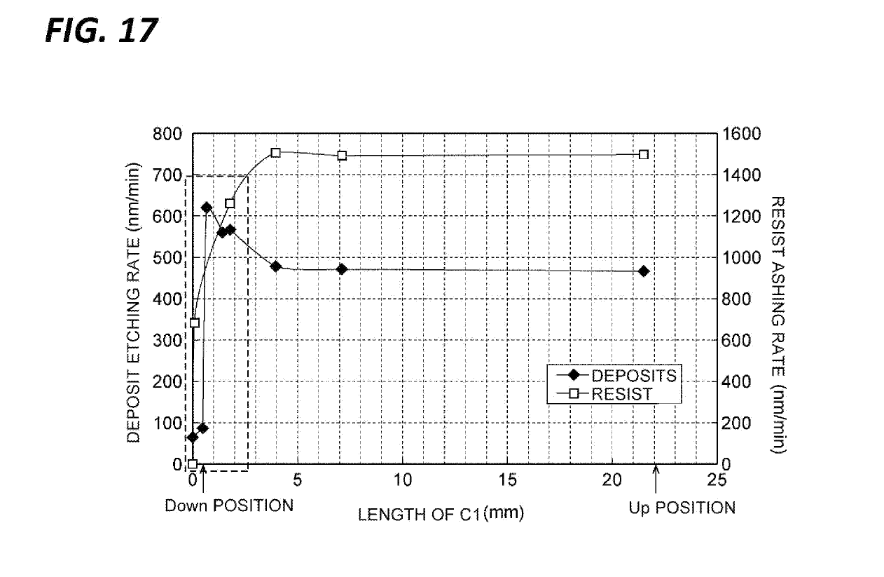

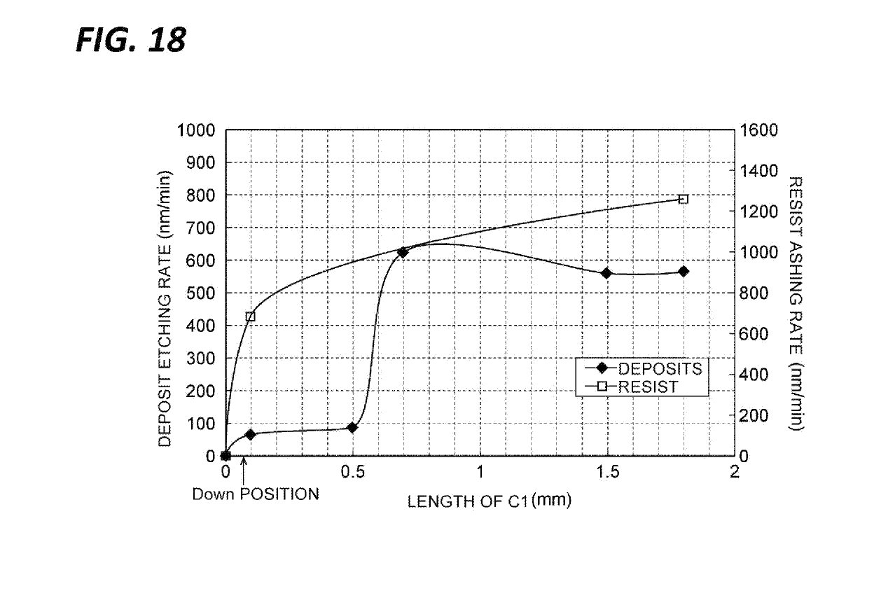

FIG. 17 is a graph illustrating the relationship between the etching rate and the ashing rate at the end portion of the wafer W, and the length of the clearance C1, and FIG. 18 is a graph illustrating the portion indicated by dotted line in FIG. 17 in an enlarged scale. In FIGS. 17 and 18, an etching rate of deposits (an inorganic material (here, SiO₂ as an example)) and an ashing rate of a resist (an organic material) were measured and plotted while the length of the clearance C1 was varied. The horizontal axis indicates the length of the clearance C1, the left vertical axis indicates the etching rate of deposits, and the right vertical axis indicates the ashing rate of a resist. Here, an etching rate and an ashing rate at different scales are illustrated on the same graph in order to compare the respective rates in a behavior change according to a length change of the clearance C1. Accordingly, as to a legend for deposits, values on the left vertical axis are referred to, and as to a legend for a resist, values on the right vertical axis are referred to. The “Down position” illustrated in FIGS. 17 and 18 is, for example, a position of the upper ring member 51 disposed on the lower ring member 52 as illustrated in FIG. 2, and the “Up position” illustrated in FIG. 17 is, for example, a disposition position of the upper ring member 51 during carrying-in/out of the wafer W as illustrated in FIG. 4. That is, as the length of the clearance C1 is increased, the upper ring member 51 is moved to a higher position. Meanwhile, the processing conditions were as follows.

(Etching Condition)
Pressure within treatment device: 300 mTorr
Power of high-frequency power source (upper electrode/lower electrode): 0/4800 W
Flow rate of processing gas: CF₄/C₄F₈/O₂/Ar=200/70/150/100 sccm

(Ashing Condition)
Pressure within treatment device: 200 mTorr
Power of high-frequency power source (upper electrode/lower electrode): 0/2000 W
Flow rate of processing gas: O₂=350 sccm

As illustrated in FIG. 17, it was found that when the length of the clearance C1 is gradually increased from the Down position to the Up position, the etching rate and the ashing rate are gradually increased, and when the length of the clearance C1 becomes about 4 mm or more, the etching rate and the ashing rate become substantially constant values. In this manner, it was found that the ashing rate as well as the etching rate changes according to the length of the clearance C1. That is, it was found that in both the etching processing and the ashing processing, a difference in rate between the center and the end portion of the wafer W may be reduced by adjusting the length of the clearance C1. As illustrated in FIG. 18, it was found that the etching rate of deposits is not increased when the length of the clearance C1 ranged from 0 mm to about 0.5 mm, and is rapidly increased when the length ranged from about 0.5 mm to 0.7 mm. Meanwhile, it was found that the ashing rate of the resist is rapidly increased when the length of the clearance C1 ranges from 0 mm to about 0.1 mm. In this manner, it was found that in the etching processing mainly performed by ions, the clearance C1 needs to be set to be larger than in the ashing processing mainly performed by radicals.

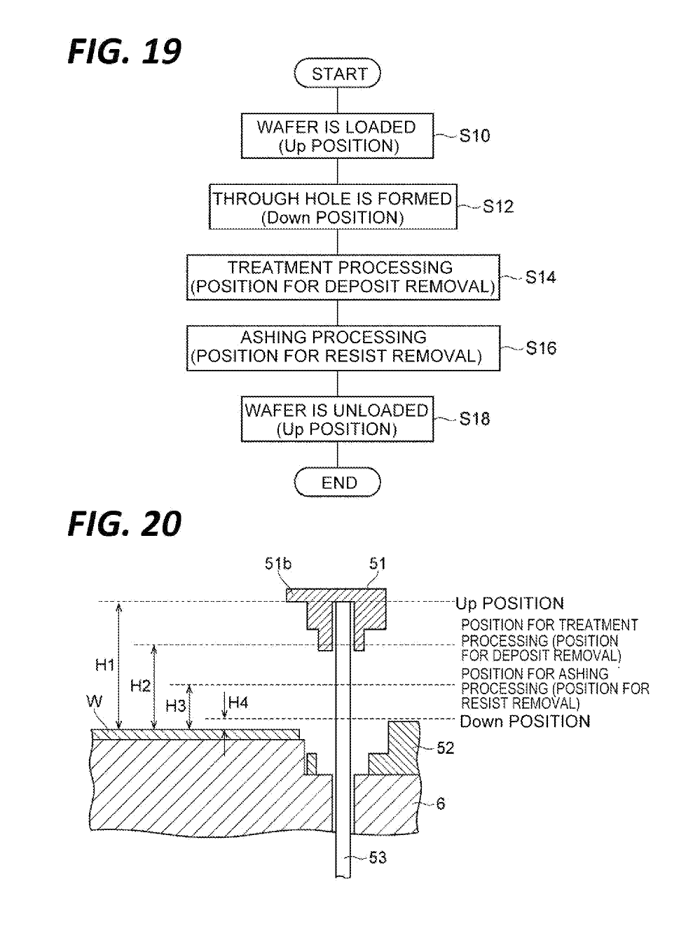

Based on the results as described above, descriptions will be made on the flow of plasma treatment when the height position (the length of the clearance C1) of the bevel covering is adjusted. FIG. 19 is a flow chart of plasma treatment when the height position (the length of the clearance C1) of the bevel covering is adjusted. The control process illustrated in FIG. 19 is executed when each configuration mechanism is operated by the above-described control unit 90.

As illustrated in FIG. 19, a wafer W is loaded and mounted on the electrostatic chuck 6 (S10). A process in S10 is the same as the carrying-in method of the wafer W as described above. That is, first, in a state where the wafer W is not supported by the electrostatic chuck 6, the upper ring member 51 is moved to the Up position. FIG. 20 is a view for explaining the height position of the upper ring member 51. As illustrated in FIG. 20, when the upper ring member 51 is moved to the Up position, the length of the clearance C1 between the bottom surface of the eave portion 51b and the top surface of the wafer W becomes H1. In this state, the wafer W coated with a resist is loaded and mounted on the electrostatic chuck 6.

Then, a through hole is formed in the wafer W by using a TSV technology (S12). First, before an etching processing, the control unit 90 causes the lift pin 53 to be lowered so as to move the upper ring member 51 to the Down position. As illustrated in FIG. 20, when the upper ring member 51 is moved to the Down position, the length of the clearance C1 between the bottom surface of the eave portion 51b and the top surface of the wafer W becomes H4 (H4<H1). In this state, an etching processing for forming the through hole is performed.

Then, a treatment processing is performed to remove deposits generated in the process of S12 and adhered on the wafer W (S14). First, the control unit 90 causes the lift pin 53 to be raised to a predetermined height so as to raise the upper ring member 51 to a position (a position for removing deposits) higher than the Down position. Accordingly, the length of the clearance C1 between the bottom surface of the eave portion 51b and the top surface of the wafer W becomes H2 (H4<H2≦H1). Then, in a state where the length of the clearance C1 is maintained at H2, an etching processing for removing the deposits is performed. In this manner, deposits adhered on the end portion of the wafer W may also be appropriately removed by moving the upper ring member 51.

Then, an ashing processing for removing a resist is performed (S14). The control unit 90 causes the lift pin 53 to be lowered so as to move the upper ring member 51 from a position for removing the deposits in S14 to a position for removing the resist. As illustrated in FIG. 20, when the upper ring member 51 is moved to the position for removing the resist, the length of the clearance C1 between the bottom surface of the eave portion 51b and the top surface of the wafer W becomes H3 (H4<H3≦H2≦H1). Then, in a state where the length of the clearance C1 is maintained at H3, an ashing processing for removing the resist is performed. In this manner, the resist at the end portion of the wafer W and the resist at the central portion may be removed at the same rate by moving the upper ring member 51. That is, the in-plane uniformity in ashing rate may be improved.

Then, the wafer W is unloaded (S18). In the process of S18, first, the upper ring member 51 is moved to the Up position. In this state, the wafer W is unloaded. When the process of S18 is finished, the control process illustrated in FIG. 19 is finished.

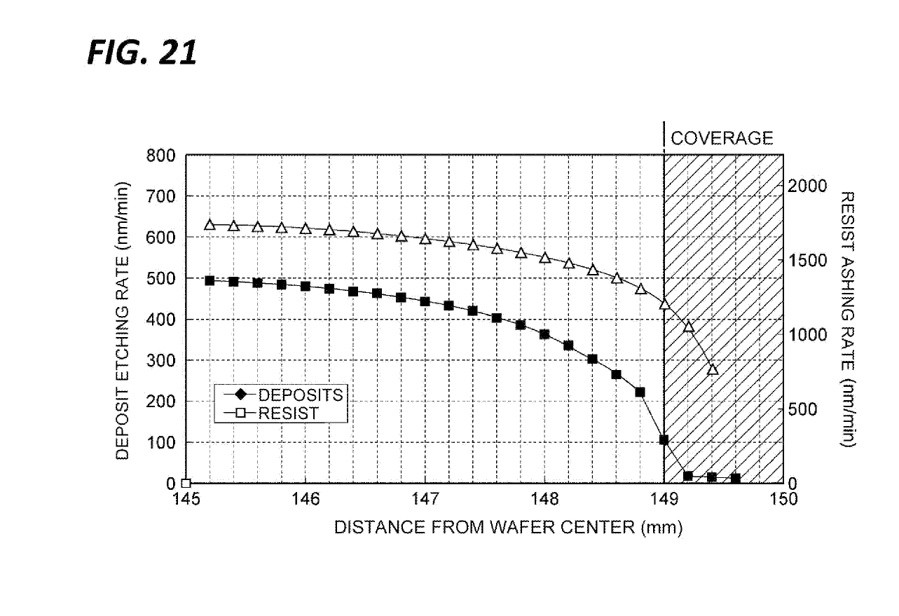

FIGS. 21 and 22 are graphs illustrating the position dependence of an etching rate of deposits (an inorganic material: here, SiO₂ as an example) and an ashing rate of a resist (an organic material). FIG. 21 is a graph when an etching processing and an ashing processing were performed while the upper ring member 51 was disposed at a Down position (a length of a clearance C1 ranged from 0.1 mm to 0.25 mm), and FIG. 22 is a graph when an etching processing and an ashing processing were performed while the upper ring member 51 was disposed at an Up position (a length of a clearance C1 was 22.5 mm). The horizontal axis indicates a distance from the wafer center, the left vertical axis indicates the etching rate of deposits, and the right vertical axis indicates the ashing rate of a resist. Herein, an etching rate and an ashing rate at different scales are illustrated on the same graph in order to compare the respective rates in a behavior change according to a distance change from the wafer center. Accordingly, as to a legend for deposits, values on the left vertical axis are referred to, and as to a legend for a resist, values on the right vertical axis are referred to. In the graph, a coverage is a region located vertically just below the eave portion 51b of the upper ring member 51. The etching condition and the ashing condition were the same as those in FIGS. 17 and 18.

As illustrated in FIG. 21, when the etching processing and the ashing processing were performed while the upper ring member 51 was disposed at the Down position, it was found that the etching rate and the ashing rate of the coverage were reduced as compared to the etching rate and the ashing rate in regions other than the coverage. In particular, it was found that the etching rate was significantly reduced, and thus the deposits were not appropriately removed. Meanwhile, as illustrated in FIG. 22, when the etching processing and the ashing processing were performed while the upper ring member 51 was disposed at the Up position, it was found that the etching rate and the ashing rate of the coverage were substantially the same as the etching rate and the ashing rate in regions other than the coverage. That is, it was found that when the upper ring member 51 was disposed at the Up position, the in-plane uniformity in etching rate and ashing rate was improved.

Although exemplary embodiments have been described, the present disclosure is not limited to these particular exemplary embodiments, and various modifications and changes may be possible within the scope of the spirit of the present disclosure described in claims.

For example, in the above-described exemplary embodiments, it has been described, as an example, that a substrate mounting table is disposed at a lower portion of a processing chamber. However, the substrate mounting table may be disposed at an upper portion of the processing chamber while a supporting surface of the substrate mounting table is downward.

### EXAMPLES

Hereinafter, Examples and Comparative Examples which were performed by the inventors will be described in order to explain the effects as described above.

(Comparison of Temperature Uniformity)

A temperature uniformity in the wafer plane was verified through a simulation by using a substrate mounting table in which a diameter of a supporting surface 6e was varied. The diameter of a wafer W was 300 mm.

### Example 1

The diameter of the supporting surface 6e was 302 mm. As the wafer W, a silicon wafer was used.

### Example 2

The diameter of the supporting surface 6e was 302 mm. As the wafer W, a quartz wafer was used.

### Comparative Example 1

The diameter of the supporting surface 6e was 296 mm. As the wafer W, a silicon wafer was used.

### Comparative Example 2

The diameter of the supporting surface 6e was 296 mm. As the wafer W, a quartz wafer was used.

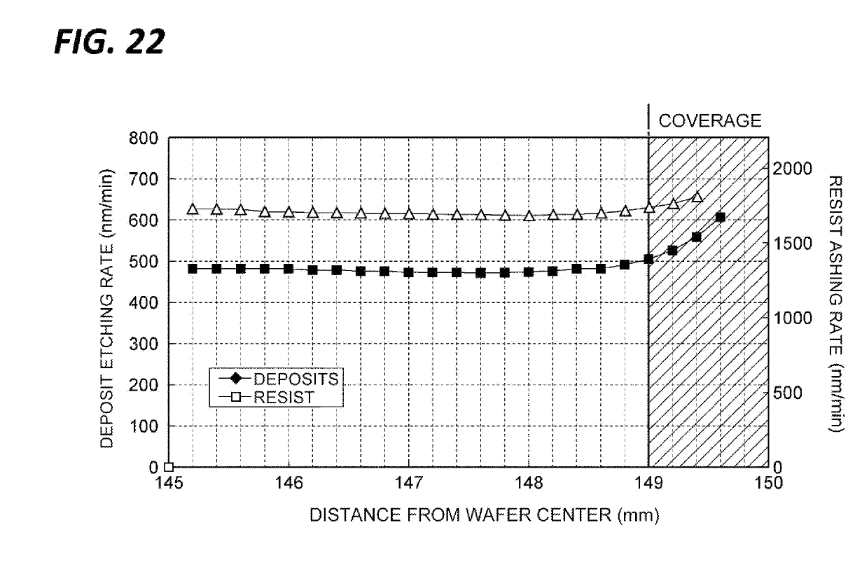

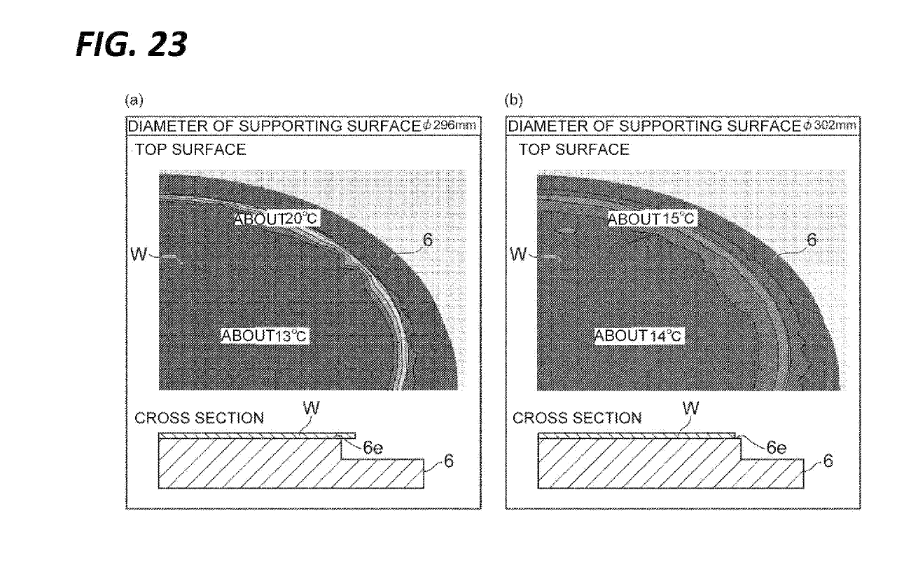

The simulation results of Example 1 and Comparative Example 1 are illustrated in FIG. 23. FIG. 23A illustrates a simulation result of Comparative Example 1, and FIG. 23B illustrates a simulation result of Example 1. In FIG. 23, a temperature is expressed according to the hue. As illustrated in FIG. 23A, in Comparative Example 1, a temperature at the central side of the silicon wafer was about 13° C., and a temperature at the outer periphery portion was about 20° C. That is, a temperature difference between the central side and the outer periphery portion of the silicon wafer was about 7° C. Meanwhile, in FIG. 23A, contour lines (about 1.75° C. interval) are illustrated, and thus, it can be seen that a non-uniformity in temperature at the periphery portion occurred. Meanwhile, as illustrated in FIG. 23B, in Example 1, the temperature at the central side of the silicon wafer was about 14° C., and the temperature at the outer periphery portion was about 15° C. That is, the temperature difference between the central side and the outer periphery portion of the silicon wafer was about 1° C. Meanwhile, in FIG. 23B, contour lines (about 0.3° C. interval) are illustrated, and thus, it can be seen that a non-uniformity in temperature did not occur even at the periphery portion. In this manner, it was found that when the supporting surface 6e comes in contact with the entire rear surface of the wafer W, the temperature difference between the central side and the outer periphery portion of the silicon wafer is improved.

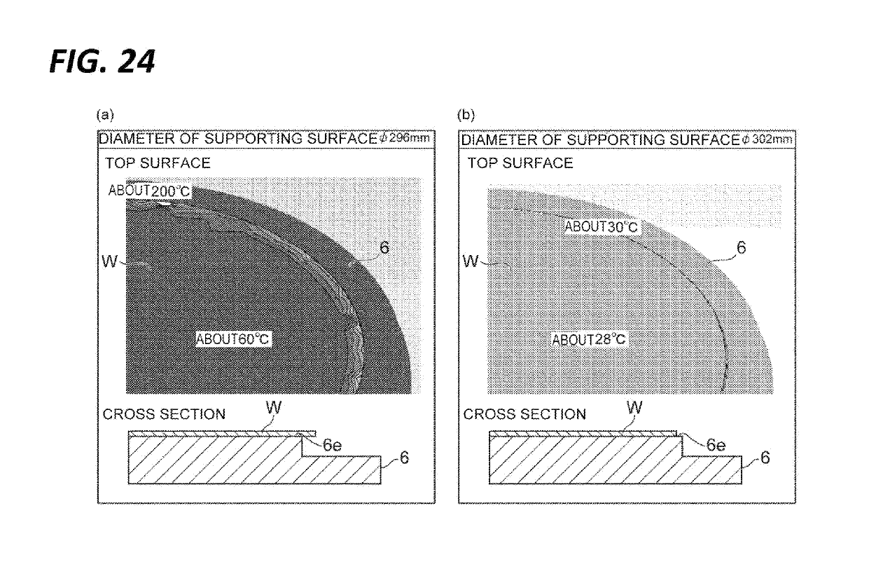

The simulation results of Example 2 and Comparative Example 2 are illustrated in FIG. 24. FIG. 24A illustrates a simulation result of Comparative Example 2, and FIG. 24B illustrates a simulation result of Example 2. In FIG. 24, a temperature is expressed according to the hue. As illustrated in FIG. 24A, in Comparative Example 2, the temperature at the central side of the quartz wafer was about 60° C., and the temperature at the outer periphery portion was about 200° C. That is, the temperature difference between the central side and the outer periphery portion of the quartz wafer was about 140° C. It was found that in the quartz wafer, a very large temperature difference occurred, as compared to in the silicon wafer. It is believed that this is because the quartz wafer is a heat-insulating material, and thus is not likely to lose heat. Meanwhile, in FIG. 24A, contour lines (about 28° C. interval) are illustrated, and thus, it can be seen that a non-uniformity in temperature occurred at the periphery portion. Meanwhile, as illustrated in FIG. 24B, in Example 2, the temperature at the central side of the quartz wafer was about 28° C., and the temperature at the outer periphery portion was about 30° C. That is, the temperature difference between the central side and the outer periphery portion of the silicon wafer was about 2° C. Meanwhile, in FIG. 24B, contour lines (about 0.3° C. interval) are illustrated, and thus, it can be seen that a non-uniformity in temperature did not occur even at the periphery portion. In this manner, it was found that when the supporting surface 6e comes in contact with the entire rear surface of the wafer W, the temperature difference between the central side and the outer periphery portion is improved even in a case where the quartz wafer that is a heat insulating material is used. That is, it was suggested that even in a bonded substrate including a quartz wafer, the temperature in the substrate plane may be uniform.

(Comparison of Electric Field Distribution)

Then, in a substrate mounting table of which the diameter of a supporting surface 6e was varied, an electric field distribution of a sheath below a bevel covering 5 was simulated. The material for the bevel covering 5 was quartz, the sheath was 5 mm, and the applied voltage was 1 W (100 MHz).

### Example 3

The diameter of the supporting surface 6e was 302 mm.

### Comparative Example 3

The diameter of the supporting surface 6e was 290 mm.

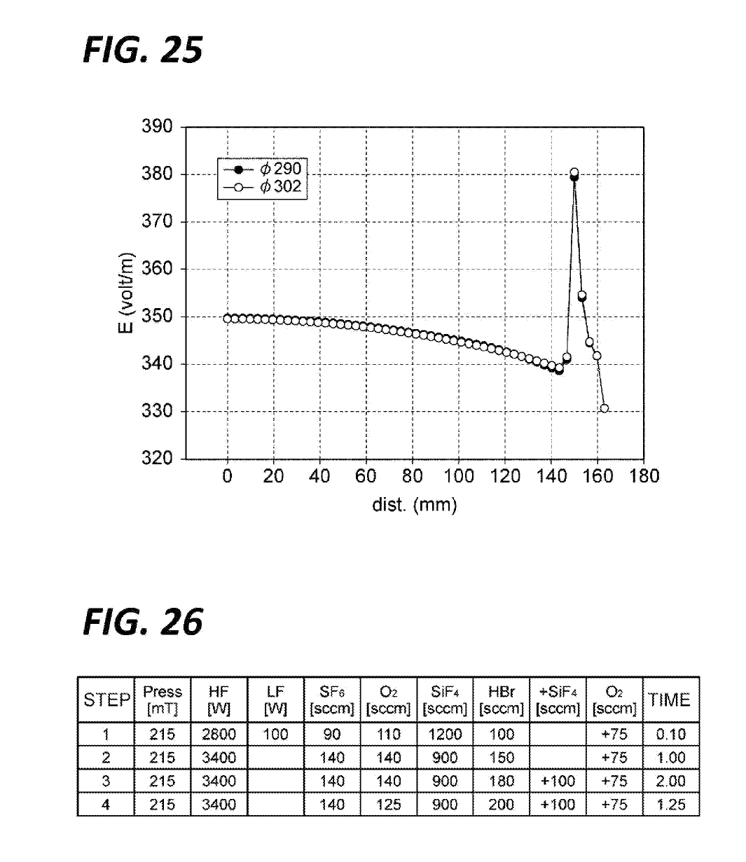

The simulation results of Example 3 and Comparative Example 3 are illustrated in FIG. 25. In FIG. 25, the horizontal axis indicates a distance (mm) from the center of the substrate mounting table, and the vertical axis indicates an electric field E (Volt/m). The results of Example 3 are indicated by white circles, and the results of Comparative Example 3 are indicated by black circles. As illustrated in FIG. 25, it was found that when the bevel covering 5 was used, there was no large difference in the electric field distribution even in a case where the diameter of the supporting surface 6e was varied. That is, it was found that the protrusion amount of the eave portion 5b of the bevel covering 5 had a dominant influence on the electric field distribution, as compared to the diameter of the supporting surface 6e. Accordingly, it was found that even in a case where the diameter of the supporting surface 6e is varied (that is, the diameter of the supporting surface 6e is changed to be equal to or greater than the diameter of the wafer W), it is possible to apply the measurement result that an inclination angle of a through hole V in the vertical direction is suppressed from occurring at the outer periphery portion WE of the wafer W by adjusting an eave amount of the bevel covering 5 when the through hole V is formed by etching the wafer W formed with a resist pattern. That is, it was found that even if the diameter of the supporting surface 6e is varied, a method which achieves optimization of a hole shape is applicable.

(Comparison of Uniformity in Hole Depth)

Then, in a substrate mounting table of which the diameter of a supporting surface 6e was varied, a hole shape and a hole depth were verified in each etching.

### Example 4

The diameter of the supporting surface 6e was 302 mm. As a wafer, a silicon wafer applied with a resist was used. The diameter of the wafer was 300 mm. Holes with a depth of 55 μm were formed at positions 75 mm, 115 mm, 130 mm, 140 mm, and 145 mm from the center (0 mm) of the wafer. Conditions for forming holes were those in illustrated in FIG. 26. As illustrated in FIG. 26, holes were formed under the conditions of four steps. In step 1, the pressure within the processing space was 215 mTorr, the high frequency power (100 MHz) of the RF power source was 2800 W, the high frequency power for bias (3.2 MHz) was 100 W, and the processing time was 10 sec. A condition of a processing gas was as follows: SF₆ for generating F radicals which contribute to silicon etching, at 90 sccm, SiF₄ for generating F radicals which contribute to silicon etching and forming a SiO₂ film which protects a hole side wall, at 1200 sccm, O₂ for forming a SiO₂ film which protects a hole side wall, at 110 sccm (75 sccm was added during the processing), and HBr for controlling a hole shape, at 100 sccm. Meanwhile, the reason for introducing the high frequency power for bias (3.2 MHz) is to suppress cracks from occurring in the boundary between the resist and the silicon wafer. In step 2, the pressure within the processing space was 215 mTorr, the high frequency power (100 MHz) of the RF power source was 3400 W, and the processing time was 60 sec. A condition of a processing gas was as follows: SF₆ at 140 sccm, SiF₄ at 900 sccm, O₂ at 140 sccm (75 sccm was added during the processing), and HBr at 150 sccm. Meanwhile, the reason for increasing HBr is to laterally widen the shape of the bottom. This is because SiF₄ generated by a reaction of SF₆ hardly escapes from the hole in accordance with the depth, and thus the bottom shape becomes tapered. In step 3, the pressure within the processing space was 215 mTorr, the high frequency power (100 MHz) of the RF power source was 3400 W, and the processing time was 120 sec. A condition of a processing gas was as follows: SF₆ at 140 sccm, SiF₄ at 900 sccm (100 sccm was added during the processing), O₂ at 140 sccm (75 sccm was added during the processing), and HBr at 180 sccm. In step 4, the pressure within the processing space was 215 mTorr, the high frequency power (100 MHz) of the RF power source was 3400 W, and the processing time was 85 sec. A condition of a processing gas was as follows: SF₆ at 140 sccm, SiF₄ at 900 sccm (100 sccm was added during the processing), O₂ at 125 sccm (75 sccm was added during the processing), and HBr at 200 sccm. Meanwhile, since a desired depth of the hole was 55 μm, the total processing time was set as 4 min 35 sec, but may be set to be longer in accordance with the depth of the hole. For example, in a case of a bonded wafer requiring a TSV technology, the hole depth is required to be 100 μm or more, and thus the a longer processing time has to be set. The holes formed under the conditions as described above were observed by a cross-sectional SEM.

### Example 5

Holes were formed at positions 75 mm, 115 mm, 130 mm, 140 mm, 145 mm, and 147 mm from the center (0 mm) of the wafer. Other conditions were the same as those in Example 4.

### Comparative Example 4

The diameter of the supporting surface 6e was 290 mm. Other conditions were the same as those in Example 4.

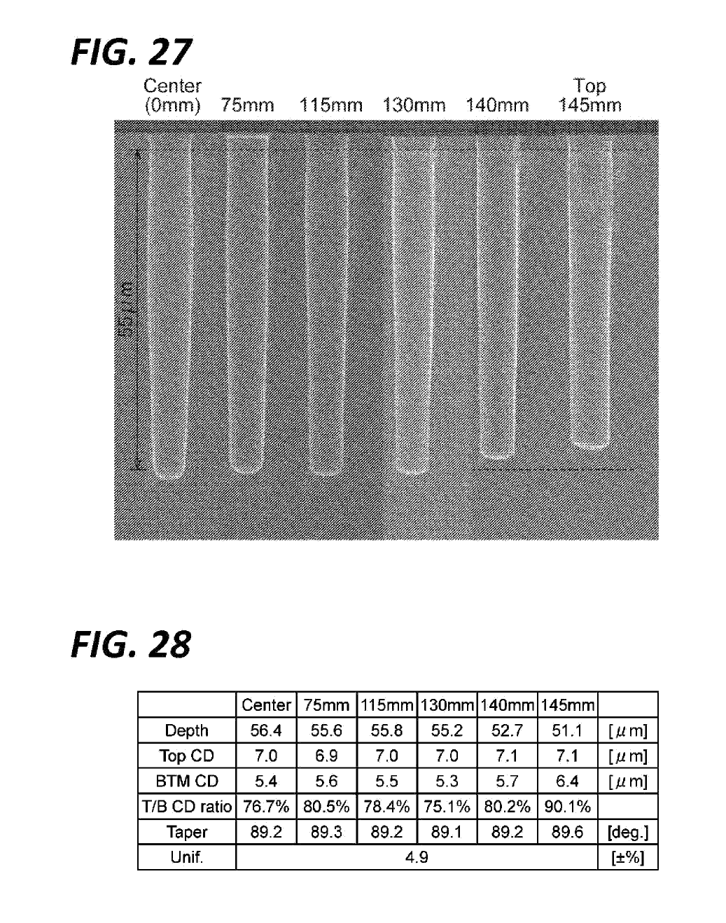

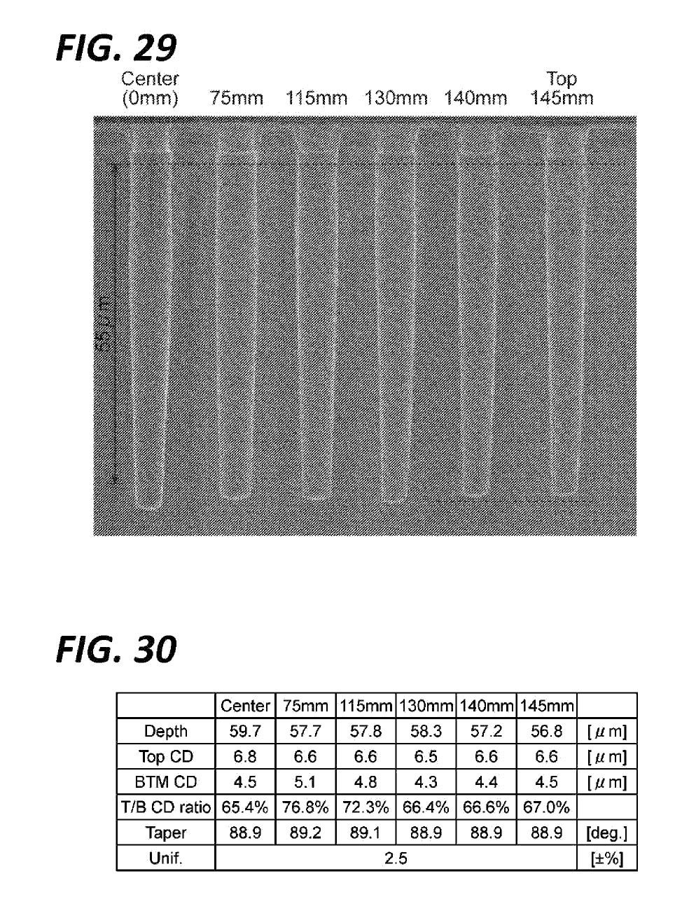

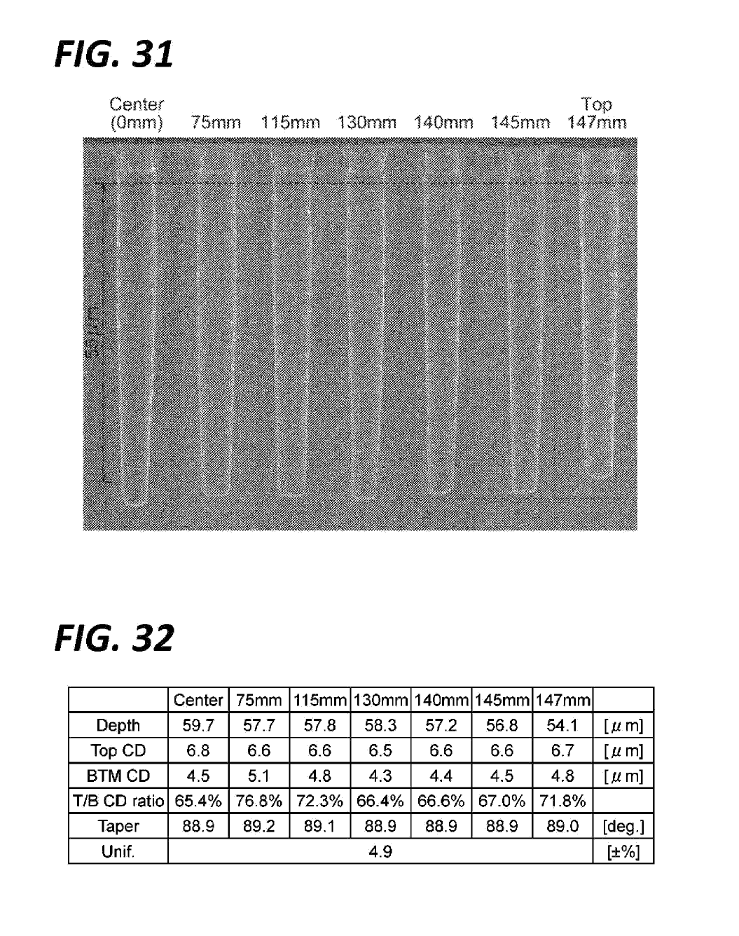

FIG. 27 illustrates a cross-sectional SEM image of Comparative Example 4. FIG. 28 illustrates data indicating shapes and depths of holes illustrated in FIG. 27. In FIG. 28, “Depth” indicates a depth of the hole, “Top CD” indicates a diameter of a top portion of the hole, “BTM CD” indicates a diameter of a bottom of the hole, “T/B CD ratio” indicates a ratio of “Top CD” to “BTM CD”, “Taper” indicates an inclination angle of the hole, and “Unif.” indicates a value obtained by evaluating a depth uniformity in the substrate plane. The uniformity is a value expressed as a percentage which is obtained by obtaining a maximum and a minimum of measured values of “Depth”, and dividing a difference between the maximum and the minimum by a sum of the maximum and the minimum. FIG. 29 illustrates a cross-sectional SEM image of Example 4. FIG. 30 illustrates data indicating shapes and depths of holes illustrated in FIG. 29. FIG. 31 illustrates a cross-sectional SEM image of Example 5. FIG. 32 illustrates data indicating shapes and depths of holes illustrated in FIG. 31.

As illustrated in FIGS. 27 and 21, in Comparative Example 4, it was found that since in the region 140 mm outward from the region at the central side, the depth of the hole became shallow, the uniformity in depth became 4.9%. In contrast, as illustrated in FIGS. 29 and 23, in Example 4, it was found that since in the region 140 mm outward from the region at the central side, the depth of the hole was improved, the uniformity in depth became 2.5%. In this manner, it was found that when the supporting surface 6e comes in contact with the entire rear surface of the wafer W, the uniformity in hole depth is improved. In Comparative Example in which the uniformity in depth was calculated in consideration of a region 145 mm outward from the center, the uniformity in depth was 6.7%, while as illustrated in FIGS. 31 and 25, it was found that in Example 5, the uniformity in depth became 4.9%. Accordingly, it was found that when the supporting surface 6e comes in contact with the entire rear surface of the wafer W, the uniformity in hole depth is improved.

### DESCRIPTION OF SYMBOLS

1: processing chamber, 2: mounting table, 4: support, 5: bevel covering, 5b: eave portion, 6: electrostatic chuck, 16: shower head, 51: upper ring member, 52: lower ring member, 90: control unit.

1. A substrate mounting table disposed within a processing chamber and configured to support a circular substrate to be processed, the processing chamber being configured to accommodate the substrate and perform a plasma processing, the substrate mounting table comprising:
a substrate supporting unit which has a circular supporting surface which comes in contact with an entire rear surface of the substrate, and supports the substrate by the supporting surface; and
an annular cover member having an outer diameter larger than the supporting surface and an inner diameter smaller than the substrate,
wherein the cover member is disposed to surround a periphery of the substrate supported by the supporting surface when viewed in a direction perpendicular to the supporting surface.

2. The substrate mounting table of claim 1, wherein the supporting surface is one side surface of the substrate supporting unit formed in a cylindrical shape, and has a diameter equal to or larger than a diameter of the substrate.

3. The substrate mounting table of claim 1, wherein the cover member is disposed so that a central axis of the cover member is coaxial with a central axis of the substrate supporting unit.

4. The substrate mounting table of claim 1, wherein the cover member is disposed to cover a portion between a periphery of the substrate and a position spaced 0.3 mm to 10 mm apart from the periphery of the substrate.

5. The substrate mounting table of claim 1, wherein an inner diameter of the cover member is formed to be smaller than an outer diameter of the substrate by 0.3 mm to 1.0 mm.

6. The substrate mounting table of claim 1, wherein the cover member is disposed so that a gap is formed between a front surface of the substrate and a rear surface of the cover member which faces the front surface of the substrate.

7. The substrate mounting table of claim 1, wherein the cover member includes:
a ring-shaped main body having an inner diameter larger than a diameter of the supporting surface, and
an eave portion provided at one end side of an inner periphery of the main body and protruding radially inward from the main body to form the inner diameter of the cover member.

8. The substrate mounting table of claim 1, wherein the substrate supporting unit supports a bonded substrate as the substrate, the bonded substrate being formed by bonding a plurality of substrate to each other.

9. The substrate mounting table of claim 8, wherein the substrate supporting unit supports a bonded substrate as the substrate, the bonded substrate being formed by bonding a plurality of substrates including substrates made of quartz glass to each other.

10. A plasma treatment device comprising:
a processing chamber configured to accommodate a circular substrate to be processed and perform a plasma processing; and
a substrate mounting table disposed within the processing chamber and configured to support the substrate,
wherein the substrate mounting table includes:
a substrate supporting unit which has a circular supporting surface which comes in contact with an entire rear surface of the substrate, and supports the substrate by the supporting surface; and
an annular cover member having an outer diameter larger than the supporting surface and an inner diameter smaller than the substrate,
wherein the cover member is disposed to surround a periphery of the substrate supported by the supporting surface when viewed in a direction perpendicular to the supporting surface.
